(19) United States
(12) Patent Application Publication
(10) Pub. No.: US 2025/0268042 A1
(43) Pub. Date: Aug. 21, 2025

(54) DISPLAY DEVICE AND MANUFACTURING METHOD OF THE SAME

(71) Applicant: Samsung Display Co., Ltd., Yongin-Si (KR)

(72) Inventors: DAEGEUN LEE, Yongin-si (KR); HANHO PARK, Yongin-si (KR); JOONGMOK LEE, Yongin-si (KR)

(21) Appl. No.: 19/052,274

(22) Filed: Feb. 13, 2025

(30) Foreign Application Priority Data
Feb. 19, 2024 (KR) 10-2024-0023794
Apr. 3, 2024 (KR) 10-2024-0045428

(51) Int. Cl. H10K 59/131; H05K 1/18; H10K 59/12; H10K 59/80

(52) U.S. Cl. CPC H10K 59/131; H05K 1/189; H10K 59/1201; H10K 59/8792; H05K 2201/10128

(57) ABSTRACT

A display device includes a display panel including panel pads at least partially extending in a first direction and arranged in a second direction and a flexible circuit board including circuit pads electrically connected to the panel pads. The panel pads include display pads and at least one panel alignment pad spaced apart from the plurality of display pads in the second direction. The circuit pads include functional pads respectively electrically connected to the plurality of display pads and at least one circuit alignment pad extending in the first direction and spaced apart from the functional pads in the second direction. The circuit alignment pad includes a first portion and a second portion spaced apart from the first portion in the first direction to form a separation portion. The at least one panel alignment pad overlaps the separation portion between the first portion and the second portion.

### CROSS-REFERENCE TO RELATED APPLICATIONS

This U.S. non-provisional patent application claims priority, under 35 U.S.C. § 119, from Korean Patent Application Nos. 10-2024-0023794 filed on Feb. 19, 2024 and 10-2024-0045428, filed on Apr. 3, 2024, the entire contents of which are hereby incorporated by reference.

### BACKGROUND

The present disclosure herein relates to a display device and a method of manufacturing the same, and more particularly, to a display device with improved reliability by being able to measure the degree of alignment of a display panel and a flexible printed circuit board during the bonding process of the display panel and the flexible printed circuit board.

Display devices such as televisions, monitors, smartphones, and tablets that provide images to users include a display panel configured to display images. Various display panels such as a liquid crystal display panel, an organic light-emitting display panel, an electro wetting display panel, and an electrophoretic display panel are being developed.

Recently, with the development of display device technologies, display devices including a flexible display panel are being developed. A display panel includes a plurality of pixels that displays an image and a driving circuit for driving the pixels. To reduce the thickness of a display device, pixels are disposed in the display region of the display panel, and a flexible circuit board on which driving circuits are mounted may be connected to the non-display region of the display panel.

### SUMMARY

The present disclosure provides a display device with improved durability and reliability.

The present disclosure also provides a method of manufacturing a display device, which may easily determine the degree of alignment after a flexible circuit board is pressed during a combining process of the flexible circuit board and a display panel, and a display device manufactured therethrough.

An embodiment of the inventive concept provides a display device including a display panel including a plurality of panel pads at least partially extending in a first direction and arranged in a second direction crossing the first direction and a flexible circuit board including a plurality of circuit pads at least partially electrically connected to the panel pads. The plurality of panel pads includes a plurality of display pads extending in the first direction and arranged in the second direction and at least one panel alignment pad spaced apart from the plurality of display pads in the second direction. The plurality of circuit pads include a plurality of functional pads extending in the first direction, arranged in the second direction, and respectively electrically connected to the plurality of display pads and at least one circuit alignment pad extending in the first direction and spaced apart from the functional pads in the second direction. The at least one circuit alignment pad includes a first portion and a second portion spaced apart from the first portion in the first direction to form a separation portion. The at least one panel alignment pad overlaps the separation portion between the first portion and the second portion or is overlapping to the separated portion in the second direction.

In an embodiment, the at least one panel alignment pad may overlap each of the first portion and the second portion.

In an embodiment, the at least one circuit alignment pad may include a first outer circuit alignment pad extending in the first direction and a main circuit alignment pad spaced apart from the plurality of functional pads with the first outer circuit alignment pad interposed therebetween. The main circuit alignment pad may include the first portion and the second portion.

In an embodiment, the length of the separation portion between the first portion and the second portion in the first direction may be greater than a length of the at least one panel alignment pad in the first direction.

In an embodiment, a width of the main circuit alignment pad in the second direction may be greater than a width of the first outer circuit alignment pad in the second direction.

In an embodiment, a width of each of the first portion and the second portion in the second direction may be substantially equal to a width of the panel alignment pad in the second direction.

In an embodiment, the at least one panel alignment pad may include a first panel alignment pad extending in the first direction and a second panel alignment pad extending in the first direction and spaced apart from the first panel alignment pad in the second direction. The at least one circuit alignment pad may be disposed between the first panel alignment pad and the second panel alignment pad.

In an embodiment, a length of the separated portion between the first portion and the second portion in the first direction may be smaller than a length of each of the first panel alignment pad and the second panel alignment pad in the first direction.

In an embodiment, the ends of the first panel alignment pad and the second panel alignment pad may be substantially parallel to each other in the second direction.

In an embodiment, the display panel may further include a panel base layer on which the plurality of panel pads are disposed. The panel base layer may be optically opaque.

In an embodiment, the flexible circuit board may further include a circuit base layer on which the plurality of circuit pads are disposed. The circuit base layer may be optically transparent.

In an embodiment, the flexible circuit board may have a virtual center line extending halfway between two edges of the circuit base layer that extend in the first direction. The plurality of circuit pads may include left circuit pads disposed to the left side of the virtual center line and right circuit pads disposed to the right side of the virtual center line. The left circuit pads may include a plurality of first functional pads extending in the first direction, arranged in the second direction, and respectively electrically connected to the plurality of display pads and at least one first circuit alignment pad extending in the first direction and spaced apart from the functional pad in the second direction. The right circuit pads may include a plurality of second functional pads extending in the first direction, arranged in the second direction, and respectively electrically connected to the plurality of display pads and at least one second circuit alignment pad extending in the first direction and spaced apart from the functional pad in the second direction. The at least one first circuit alignment pad may include a (1-1)-th portion and a (2-1)-th portion spaced apart from the (1-1)-th portion in the first direction. The at least one second circuit alignment pad may include a (1-2)-th portion and a (2-2)-th portion spaced apart from the (1-2)-th portion in the first direction.

In an embodiment, display device may further include a data driving circuit connected to at least some of the plurality of functional pads.

In an embodiment of the inventive concept, a display device may further include a conductive adhesive film disposed between the display panel and the flexible circuit board and electrically connecting the plurality of display pads to the plurality of functional pads.

In an embodiment of the inventive concept, a display device includes a display panel including an optically opaque panel base layer and a plurality of panel pads disposed on the panel base layer, at least partially extending in a first direction, and arranged in a second direction crossing the first direction and a flexible circuit board including a plurality of circuit pads at least partially electrically connected to the plurality of panel pads. The plurality of panel pads include a plurality of display pads extending in the first direction and arranged in the second direction and at least one panel alignment pad spaced apart from the plurality of display pads in the second direction. The plurality of circuit pads include a plurality of functional pads extending in the first direction, arranged in the second direction, and respectively electrically connected to the plurality of display pads and at least one circuit alignment pad spaced apart from the plurality of functional pads in the second direction. The at least one circuit alignment pad includes a first portion and a second portion spaced apart from the first portion in the first direction. The at least one panel alignment pad is disposed to avoid overlapping the plurality of circuit pads.

In an embodiment, the at least one panel alignment pad may overlap the at least one circuit alignment pad in any one of the first direction and the second direction.

In an embodiment, the flexible circuit board may further include a circuit base layer on which the plurality of circuit pads are disposed. The circuit base layer may include a flexible material that is optically transparent.

In an embodiment of the inventive concept, a method of manufacturing a display device includes providing a display panel including a display region that displays an image and a non-display region adjacent to the display region and including a plurality of display pads disposed in the non-display region and at least one panel alignment pad, providing a flexible circuit board including a plurality of functional pads and at least one circuit alignment pad, combining the display panel and the flexible circuit board to electrically connect at least some of the plurality of functional pads to the plurality of display pads, and determining the degree of alignment of the flexible circuit board with the display panel. The plurality of display pads, the plurality of functional pads, and the at least one circuit alignment pad extend in a first direction, and the plurality of functional pads and the at least one circuit alignment pad are spaced apart from each other in a second direction crossing the first direction. The at least one circuit alignment pad includes a first portion and a second portion spaced apart from the first portion in the first direction. In the measuring of the degree of alignment in the combined state, the state of alignment between the at least one panel alignment pad and the at least one circuit alignment pad is measured.

In an embodiment, the flexible circuit board may further include a circuit base layer including a rear surface on which the plurality of circuit pads are disposed and a front surface opposing the rear surface. In the determining of the degree of alignment, the state of alignment between the at least one panel alignment pad and the at least one circuit alignment pad may be measured from the front surface side.

In an embodiment, the display panel may further include a panel base layer on which the plurality of panel pads are disposed. The panel base layer may be optically opaque.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept.

### In the Drawings:

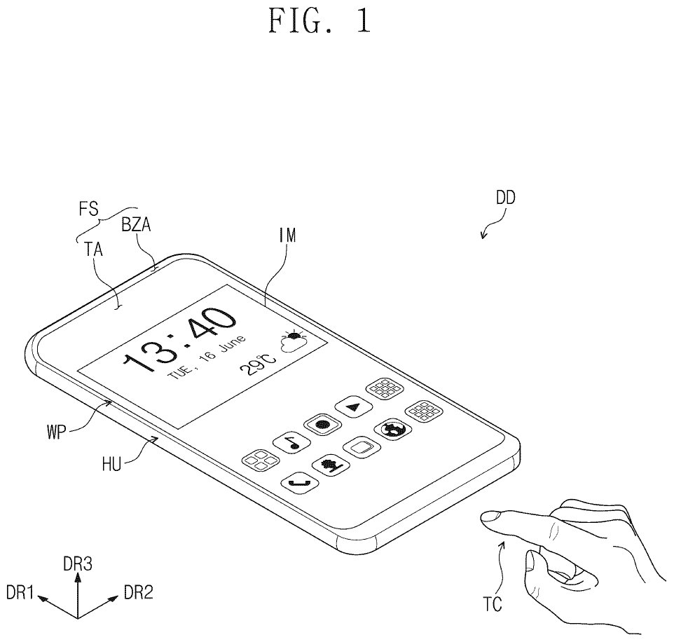

FIG. 1 is a combined perspective view of a display device according to an embodiment of the inventive concept;

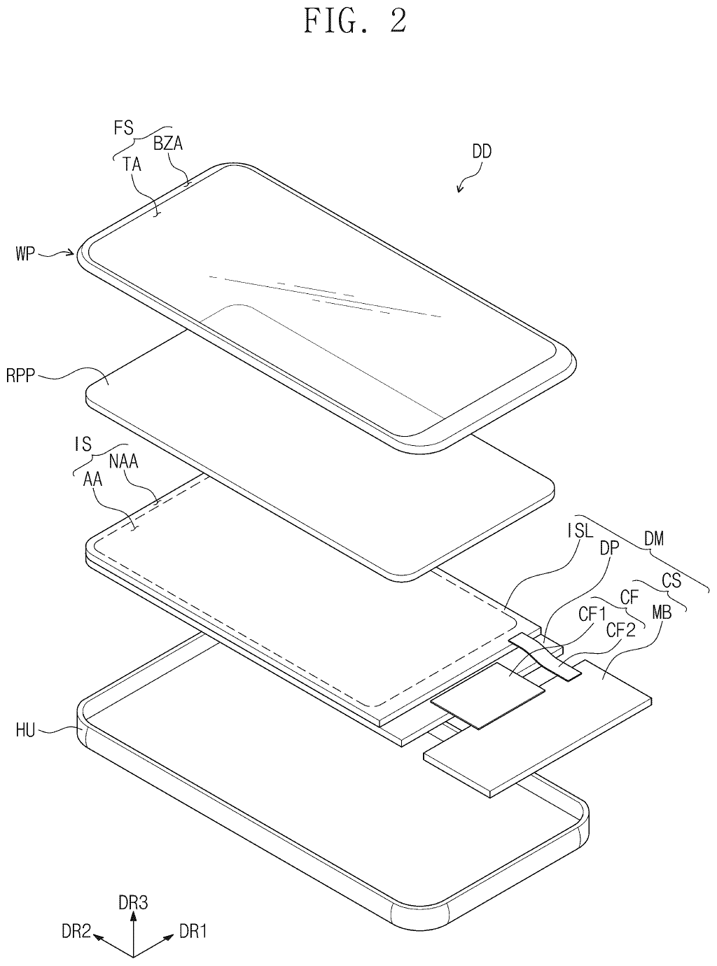

FIG. 2 is an exploded perspective view of the display device according to an embodiment of the inventive concept;

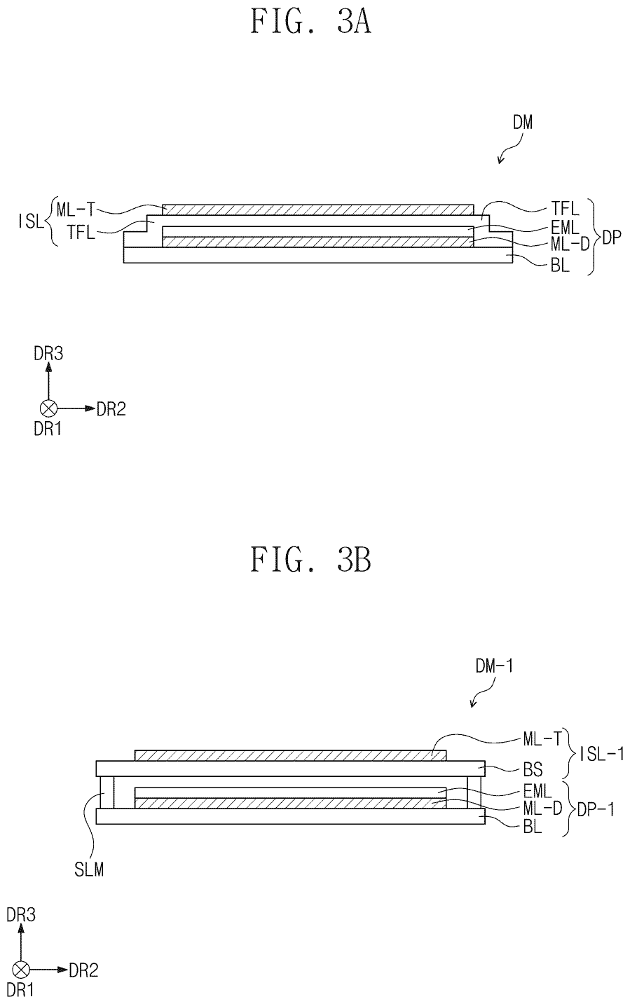

FIG. 3A is a cross-sectional view of a display module according to an embodiment of the inventive concept;

FIG. 3B is a cross-sectional view of a display module according to an embodiment of the inventive concept;

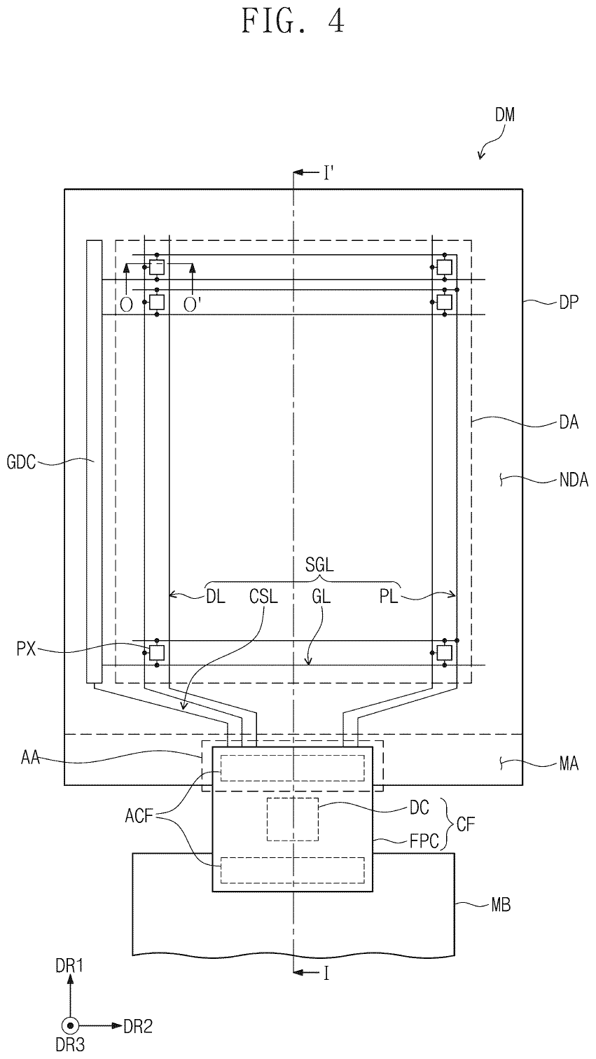

FIG. 4 is a plan view of a display module according to an embodiment of the inventive concept;

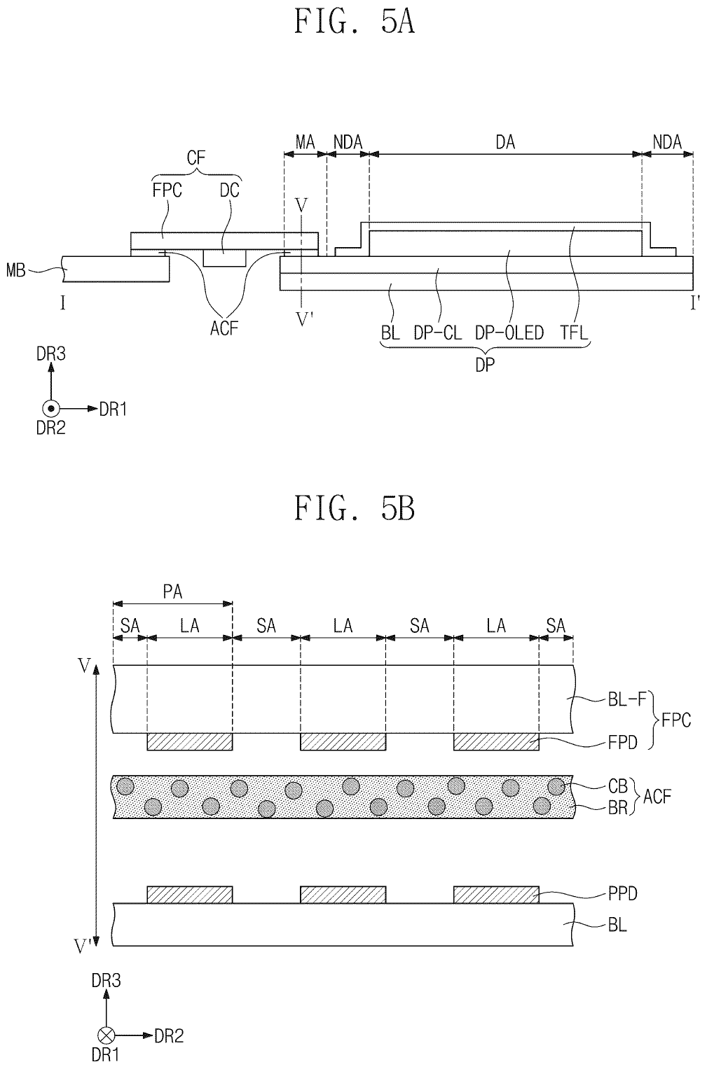

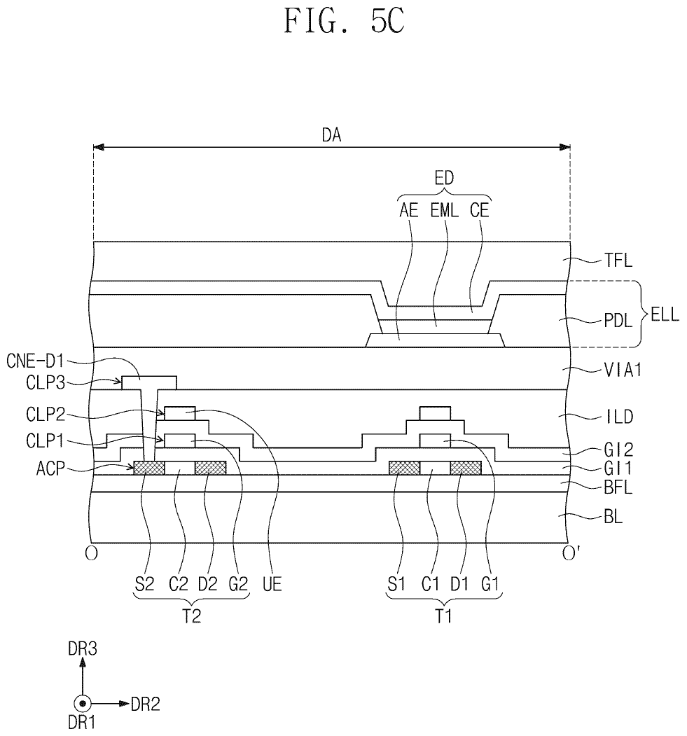

FIG. 5A is a cross-sectional view of the display module according to an embodiment of the inventive concept;

FIG. 5B is a cross-sectional view of a portion of the display module according to an embodiment of the inventive concept;

FIG. 5C is a cross-sectional view of a display panel according to an embodiment of the inventive concept;

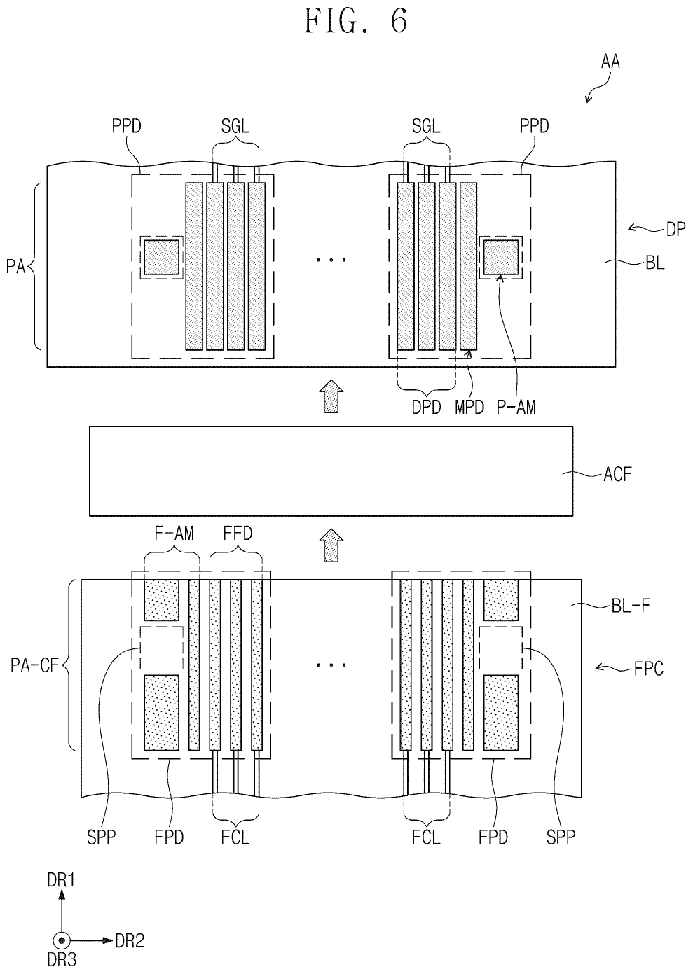

FIG. 6 is a plan view of a partial region of the display module according to an embodiment of the inventive concept;

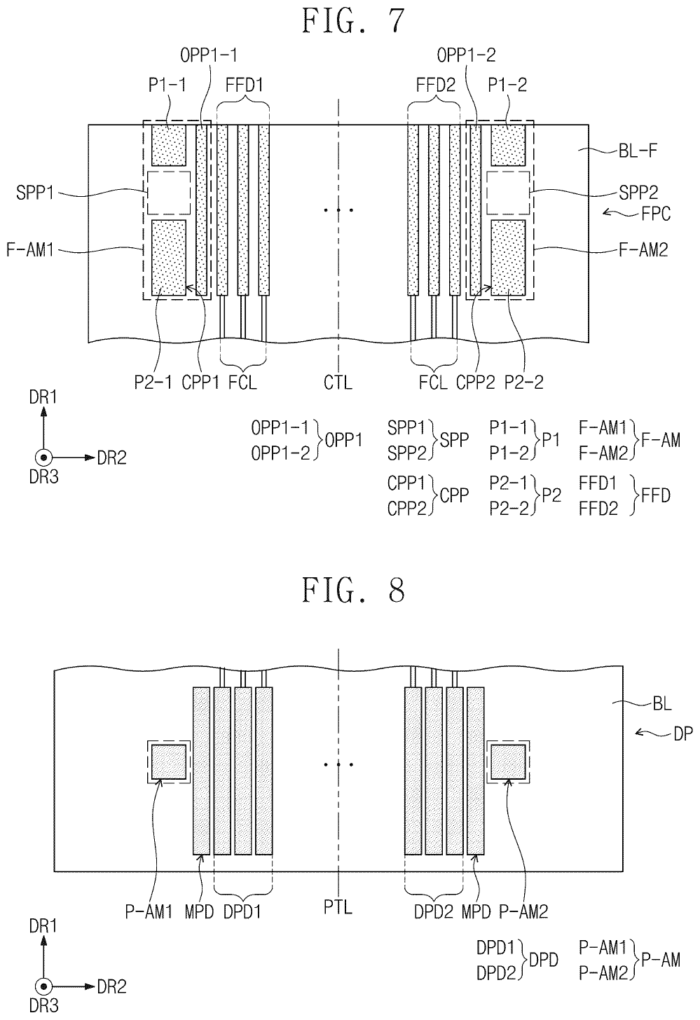

FIG. 7 is an enlarged plan view of a partial region of a flexible circuit board according to an embodiment of the inventive concept;

FIG. 8 is an enlarged plan view of a partial region of the display panel according to an embodiment of the inventive concept;

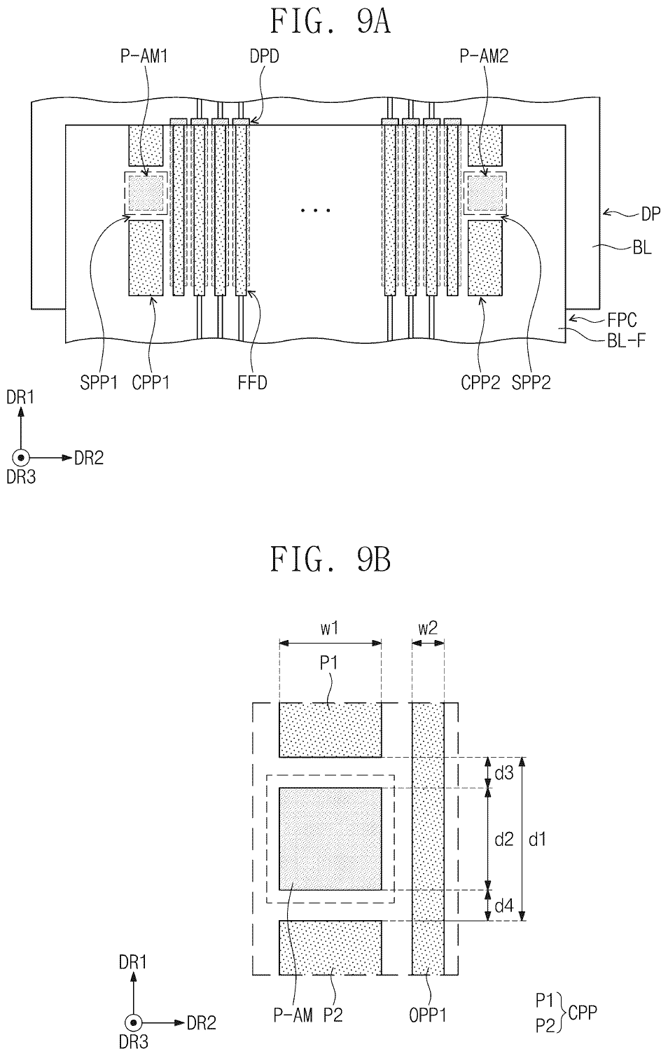

FIGS. 9A and 9B are plan views of a partial region of the display module according to an embodiment of the inventive concept;

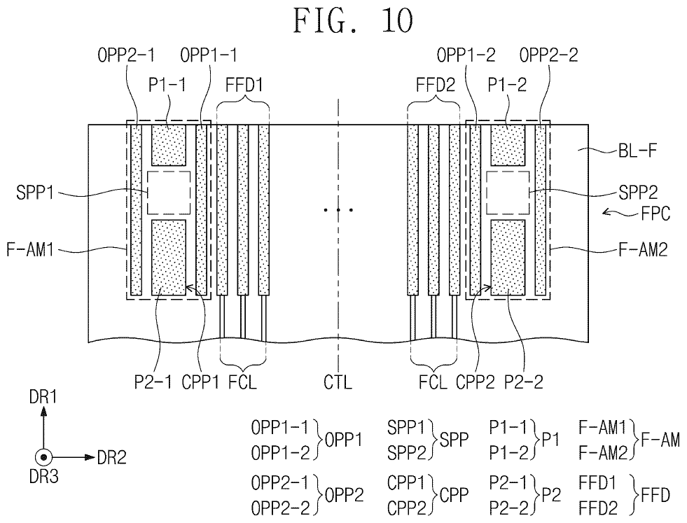

FIG. 10 is an enlarged plan view of a partial region of a flexible circuit board according to an embodiment of the inventive concept;

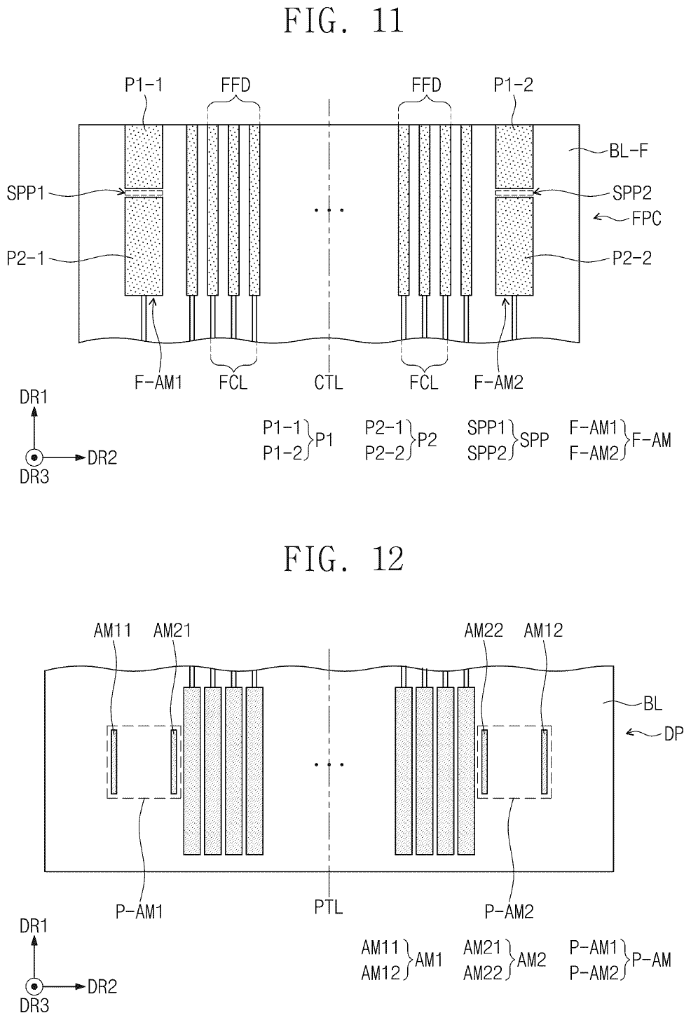

FIG. 11 is an enlarged plan view of a partial region of a flexible circuit board according to an embodiment of the inventive concept;

FIG. 12 is an enlarged plan view of a partial region of a display panel according to an embodiment of the inventive concept;

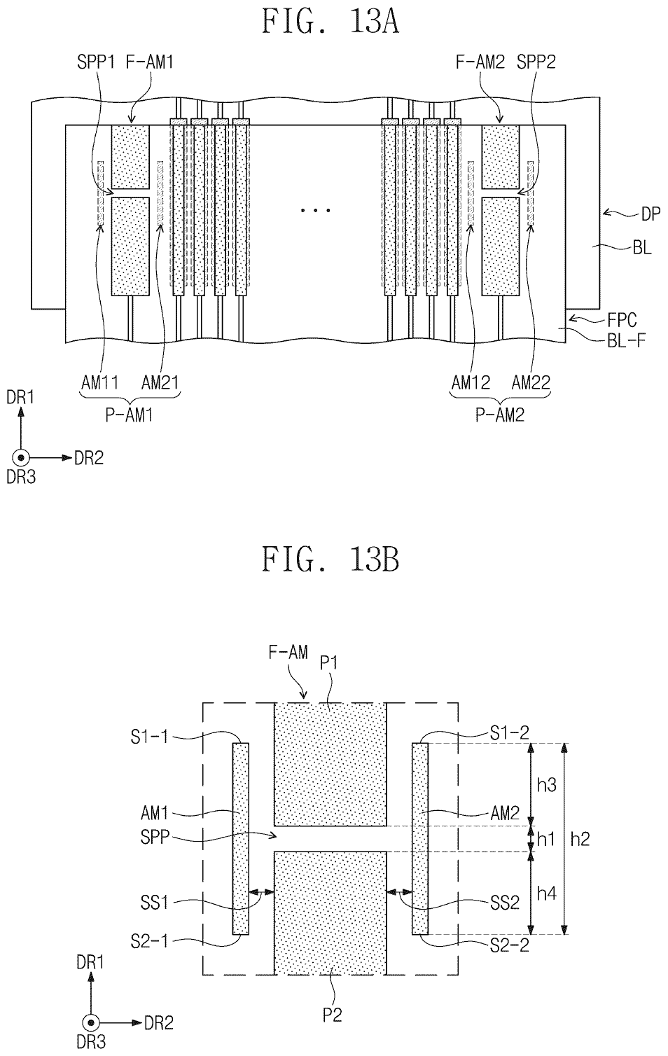

FIGS. 13A and 13B are plan views of a partial region of a display module according to an embodiment of the inventive concept;

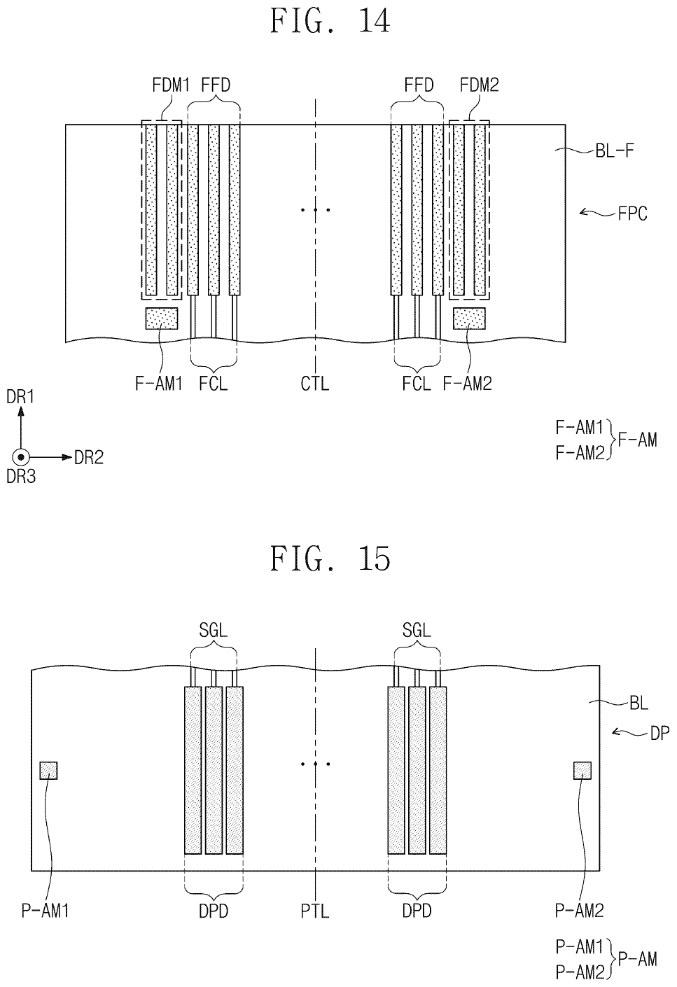

FIG. 14 is an enlarged plan view of a partial region of a flexible circuit board according to an embodiment of the inventive concept;

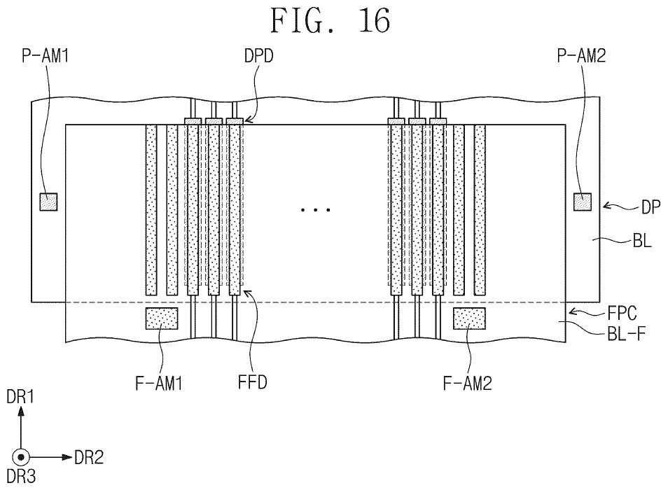

FIG. 15 is an enlarged plan view of a partial region of a display panel according to an embodiment of the inventive concept;

FIG. 16 is a plan view of a partial region of a display module according to an embodiment of the inventive concept;

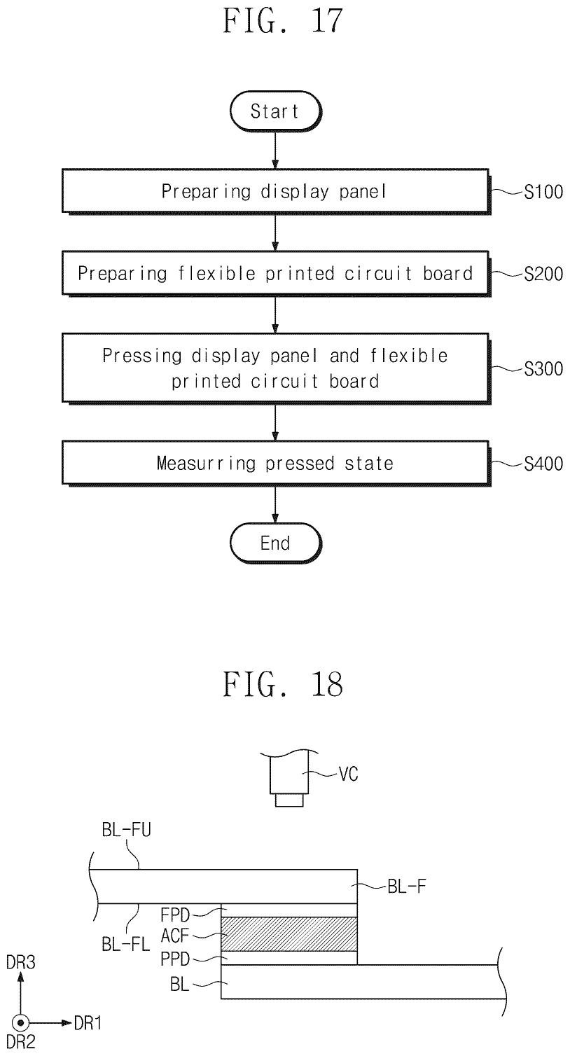

FIG. 17 is a flowchart showing a method of manufacturing a display device according to an embodiment of the inventive concept;

FIG. 18 is a cross-sectional view illustrating a portion in one step in the method of manufacturing the display device according to an embodiment of the inventive concept; and

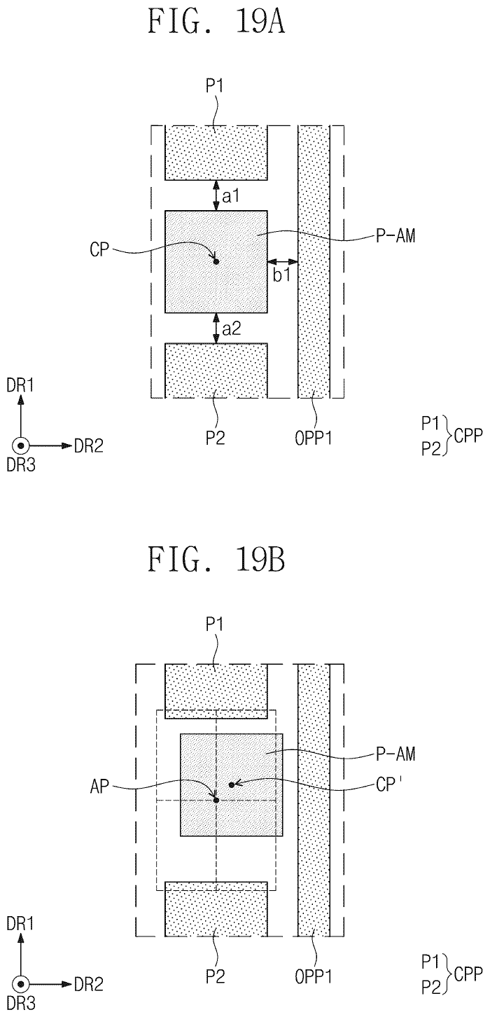

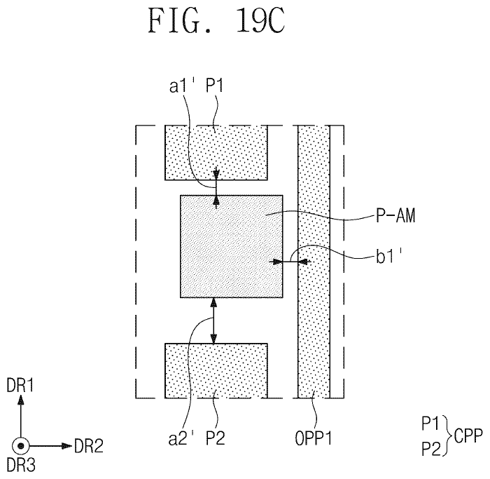

FIGS. 19A to 19C are plan views illustrating a portion in one step in the method of manufacturing the display device according to an embodiment of the inventive concept.

### DETAILED DESCRIPTION

Hereinafter, embodiments of the inventive concept will be described with reference to the drawings. In this specification, it will be understood that when an element (or region, layer, portion, etc.) is referred to as being “on”, “connected to” or “coupled to” another element, it can be directly on, connected or coupled to the other element, or intervening elements may be present between them.

Like reference numerals refer to like elements throughout. In addition, in the drawings, the thicknesses, ratios, and dimensions of elements are exaggerated for effective description of the technical contents. As used herein, the term “and/or” includes any and all combinations that the associated configurations can define.

It will be understood that, although the terms first, second, etc. may be used herein to describe various elements, these elements should not be limited to a specific order or priority by these terms. These terms are only used to distinguish one element from another element. For example, a first element could be termed a second element without departing from the scope of the present invention. Similarly, the second element may also be referred to as the first element. The terms of a singular form include plural forms unless otherwise specified.

In addition, terms, such as “below”, “lower”, “above”, “upper” and the like, are used herein for ease of description to describe one element's relation to another element(s) as illustrated in the figures. The above terms are relative concepts and are described based on the directions indicated in the drawings.

It will be understood that the terms “include” and/or “have”, when used in this specification, specify the presence of stated features, integers, steps, operations, elements, components and/or groups thereof, but do not preclude the presence or addition of one or more other features, integers, steps, operations, elements, components, and/or groups thereof.

Hereinafter, a display device according to an embodiment of the inventive concept will be described with reference to the accompanying drawings.

FIG. 1 is a combined perspective view of a display device according to an embodiment of the inventive concept. FIG. 2 is an exploded perspective view of the display device according to an embodiment of the inventive concept.

Referring to FIGS. 1 and 2, the display device DD may be activated according to an electrical signal. The display device DD may include various embodiments. For example, display devices DD may be used for small and medium-sized devices such as personal computers, laptop computers, personal digital assistants, automobile navigation units, game consoles, portable electronic devices, and cameras as well as large electronic devices such as televisions, monitors, or external billboards. These applications are presented as nonlimiting examples, and the inventive concept may be applied to other electronic devices as long as they do not depart from the concept of the present invention. For simplicity, an embodiment where the display device DD is part of a smart phone will be used in this disclosure.

The display device DD may display an image IM in a third direction DR3 on a display surface FS parallel to each of first and second directions DR1 and DR2. The image IM may include a still image as well as a dynamic image. FIG. 1 illustrates a watch window and icons as an example of the image IM. The display surface FS on which the image IM is displayed may correspond to the front surface of the display device DD and the front surface of a window panel WP.

In this embodiment, the front (or upper) and rear (or lower) surfaces of each member are defined based on a direction in which the image IM is displayed. The front and rear surfaces may face each other in the third direction DR3, such that the normal direction to each of the front and rear surfaces may be parallel to the third direction DR3. Meanwhile, directions indicated by the first to third directions DR1, DR2, and DR3 are relative concepts and may be converted into other directions. In this specification, the expression “on a plane” may mean when viewed from the third direction DR3.

The display device DD may include a window panel WP, an anti-reflection panel RPP, a display module DM, and a housing HU. In this embodiment, the window panel WP and the housing HU are coupled to each other to form the exterior of the display device DD.

The window panel WP may include an optically transparent insulating material. For example, the window panel WP may include glass or plastic. The window panel WP may have a multi-layered structure or a single-layered structure. For example, the window panel WP may include a plurality of plastic films bonded with an adhesive, or may include a glass substrate and a plastic film bonded to each other with an adhesive.

As described above, the front surface FS of the window panel WP defines the front surface of the display device DD. A transmission region TA may be an optically transparent region. For example, the transmission region TA may have a visible light transmittance of about 90% or more.

A bezel region BZA may have a relatively low light transmittance compared to the transmission region TA. The bezel region BZA outlines the shape of the transmission region TA. The bezel region BZA may be adjacent to and surround the transmission region TA.

The bezel region BZA may have a predetermined color. The bezel region BZA may cover a peripheral region NAA of the display module DM so as to block the peripheral region NAA from being viewed from the outside. Meanwhile, this is illustrated as an example, and in the window panel WP according to an embodiment of the inventive concept, the bezel region BZA may be omitted.

The anti-reflection panel RPP may be disposed below the window panel WP. The anti-reflection panel RPP reduces the reflectance of external light incident from the upper side of the window panel WP. In an embodiment of the inventive concept, the anti-reflection panel RPP may be omitted or may be included in the display module DM.

The display module DM may display an image IM and sense an external input TC. The external input TC may include various types of inputs provided from the outside of the display module DM. Inputs applied from the outside may be provided in various forms.

For example, the external input TC may include not only a touch by a part of a body such as a user's hand, but also an external input (e.g., hovering) applied at a place close to or at a predetermined close distance from the display module DM. In addition, the external input may have various forms such as force, pressure, and light and is not limited to any one embodiment. FIG. 1 illustrates a user's hand as an example of the external input TC source.

The display module DM includes a front surface IS including an active region AA and a peripheral region NAA. The active region AA may be activated according to electrical signals.

In this embodiment, the active region AA may be a region on which an image IM is displayed and an external input is sensed. The transmission region TA overlaps at least the active region AA. For example, the transmission region TA overlaps the entire surface or at least a portion of the active region AA. Accordingly, a user may view an image IM or provide an external input through the transmission region TA. However, this is illustrated as an example, and the region on which the image IM is displayed and the region on which the external input is sensed may be separated from each other within the active region AA, and the inventive concept is not limited to any one embodiment.

The peripheral region NAA may be covered by the bezel region BZA. The peripheral region NAA is adjacent to the active region AA. The peripheral region NAA may surround the active region AA. A driving circuit or driving line for driving the active region AA may be disposed in the peripheral region NAA.

The display module DM includes a display panel DP, an input sensing unit ISL, and a circuit substrate CS.

The display panel DP may be configured to substantially generate an image IM. The image IM generated by the display panel DP is visible to a user in the outside through the transmission region TA.

The input sensing unit ISL senses an external input applied from the outside. As described above, the input sensing unit ISL may sense an external input provided to the window panel WP.

The circuit substrate CS is electrically connected to the display panel DP. The circuit substrate CS includes a main circuit board MB and a flexible printed circuit board CF. The flexible printed circuit board CF may include a panel circuit board CF1 and an input circuit board CF2.

The panel circuit board CF1 is electrically connected to the display panel DP. The panel circuit board CF1 may connect the display panel DP and the main circuit board MB to each other. In this embodiment, the panel circuit board CF1 is illustrated as a flexible circuit film having an end to which the main circuit board MB is connected. However, this is illustrated as an example, and the panel circuit board CF1 may not be connected to the main circuit board MB.

The panel circuit board CF1 may be connected to pads (display pads) of the display panel DP disposed in the peripheral region NAA. The panel circuit board CF1 provides an electrical signal to the display panel DP in order to drive the display panel DP. The electrical signal may be generated in the panel circuit board CF1 or the main circuit board MB.

The circuit substrate CS may further include an input circuit board CF2 electrically connected to the input sensing unit ISL. The input circuit board CF2 may connect the input sensing unit ISL and the main circuit board MB to each other. In this embodiment, the input circuit board CF2 may be provided as a flexible circuit film and connect the input sensing unit ISL and the main circuit board MB to each other. In some embodiments, the input circuit board CF2 may not be connected to the main circuit board MB.

The input circuit board CF2 may be connected to pads (sensing pads) of the input sensing unit ISL disposed in the peripheral region NAA. The input circuit board CF2 provides an electrical signal to the input sensing unit ISL to drive the input sensing unit ISL. The electrical signal may be generated in the input circuit board CF2 or the main circuit board MB.

The main circuit board MB may include various driving circuits for driving the display module DM or a connector for power supply. Each of the panel circuit board CF1 and the input circuit board CF2 may be connected to the main circuit board MB. According to this inventive concept, the display module DM may be easily controlled through one main circuit board MB. However, this is illustrated as an example, and in the display module DM according to an embodiment of the inventive concept, the display panel DP and the input sensing unit ISL may be connected to different main circuit boards, and any one of the panel circuit board CF1 and the input circuit board CF2 may not be connected to the main circuit board MB, and the inventive concept is not limited to any one embodiment.

The housing HU is coupled to the window panel WP. The housing HU is coupled to the window panel WP to provide a predetermined internal space. The internal space may contain the display module DM.

The housing HU may include a material with relatively high rigidity. For example, the housing HU may include a plurality of frames and/or plates made of glass, plastic, or metal, or a combination thereof. The housing HU may protect the components of the display device DD that is in the internal space from an external impact.

FIG. 3A is a cross-sectional view of a display module according to an embodiment of the inventive concept.

Referring to FIG. 3A, the display module DM may include a display panel DP, an input sensing unit ISL, and a coupling member SLM.

The display panel DP according to an embodiment of the inventive concept may be a light-emitting display panel and is not particularly limited thereto. For example, the display panel DP may be an organic light-emitting display panel or a quantum dot light-emitting display panel.

The display panel DP may include a panel base layer BL, a display circuit layer ML-D, a light-emitting layer EML, and a thin film encapsulation layer TFL. The input sensing unit ISL-1 may include a base layer TFE and a sensing circuit layer ML-T. The thin film encapsulation layer TFL and the base layer TFE may have the same configuration as each other.

According to an embodiment of the inventive concept, the display panel DP and the input sensing unit ISL may be formed through a continuous process. That is, the sensing circuit layer ML-T may be formed directly on the thin film encapsulation layer TFL. The sensing circuit layer ML-T may include a plurality of insulating layers and a plurality of conductive layers. The plurality of conductive layers may constitute a sensing electrode configured to sense an external input, a sensing line connected to the sensing electrode, and a sensing pad connected to the sensing line.

The display circuit layer ML-D may be disposed on the panel base layer BL. The display circuit layer ML-D may include a plurality of insulating layers, a plurality of conductive layers, and a semiconductor layer. The plurality of conductive layers of the display circuit layer ML-D may constitute signal lines or a pixel control circuit.

The light-emitting layer EML may be disposed on the display circuit layer ML-D. The light-emitting layer EML may generate light or control light transmittance. For example, the light-emitting layer EML of the organic light-emitting display panel may include an organic light-emitting material. The light-emitting layer EML of the quantum dot light-emitting display panel may include at least any one of quantum dots or quantum rods. The light-emitting layer EML of the liquid crystal display panel may include a liquid crystal layer.

FIG. 3B is a cross-sectional view of a display module according to an embodiment of the inventive concept.

Referring to FIG. 3B, the display module DM-1 may include a display panel DP-1 and an input sensing unit ISL-1. The input sensing unit ISL-1 may also be referred to as an input sensing layer.

The display panel DP-1 may include a panel base layer BL, a display circuit layer ML-D, and a light-emitting layer EML. The input sensing unit ISL-1 may include an upper substrate BS and a sensing circuit layer ML-T.

Each of the panel base layer BL and the upper substrate BS may be a silicon substrate, a plastic substrate, a glass substrate, an insulating film, or a laminated structure including a plurality of insulating layers. The panel base layer BL may be a display substrate on which a circuit layer and a display layer are disposed.

The upper substrate BS may be disposed on the light-emitting layer EML. The upper substrate BS may be an encapsulation substrate that encapsulates the display panel DP-1. A predetermined space may be defined between the upper substrate BS and the light-emitting layer EML. The space defined between the upper substrate BS and the light-emitting layer EML may be filled with air or an inert gas. In addition, in an embodiment of the inventive concept, the space defined between the upper substrate BS and the light-emitting layer EML may be filled with a filler such as silicone-based polymer, epoxy-based resin, or acrylic-based resin. Without being limited thereto, however, the space between the light-emitting layer EML and the upper substrate BS may not be defined, and the light-emitting layer EML and the upper substrate BS may be in contact with each other.

The sensing circuit layer ML-T may be disposed on the upper substrate BS. The sensing circuit layer ML-T may include a plurality of insulating layers and a plurality of conductive layers. The plurality of conductive layers may constitute a sensing electrode configured to sense an external input, a sensing line connected to the sensing electrode, and a sensing pad connected to the sensing line.

The coupling member SLM may be disposed between the panel base layer BL and the upper substrate BS. The coupling member SLM may couple the panel base layer BL and the upper substrate BS to each other. The coupling member SLM may include an organic material such as a photo-curable resin or a photoplastic resin, or an inorganic material such as a frit seal, and the inventive concept is not limited to any one embodiment.

FIG. 4 is a plan view of a display module according to an embodiment of the inventive concept. FIG. 5A is a cross-sectional view of the display module according to an embodiment of the inventive concept. FIG. 5A illustrates a cross section taken along line I-I′ illustrated in FIG. 4.

Referring to FIGS. 4 and 5A, the display module DM according to an embodiment of the inventive concept may include a display panel DP, a flexible printed circuit board CF, and a conductive adhesive film ACF. The display module DM may include a main circuit board MB electrically connected to the flexible printed circuit board CF through the conductive adhesive film ACF. In this embodiment, the flexible printed circuit board CF may include a flexible circuit board FPC and a data driving circuit DC.

A display region DA in which pixels PX are disposed and a non-display region NDA adjacent to the display region DA may be defined in the display panel DP. A pad region PA (see FIG. 6) in which a pad electrode is disposed may be defined in the non-display region NDA. In an embodiment of the inventive concept, a mounting region MA may be defined in the display panel DP. The flexible printed circuit board CF may be coupled to the mounting region MA by the conductive adhesive film ACF. The non-display region NDA and the mounting region MA may not be distinguished from each other. The mounting region MA may be a portion of the non-display region NDA. The pad region PA may be defined in a portion of the mounting region MA. The pad region PA will be described in detail later.

As illustrated in FIG. 4, the display panel DP may display a desired image by applying a driving signal to a plurality of pixels PX. The plurality of pixels PX may be arranged in a matrix form along the first and second directions DR1 and DR2 orthogonal to each other. In an embodiment of the inventive concept, the pixels PX may include first to third pixels that respectively display red, green, and blue colors. In an embodiment of the inventive concept, the pixels PX may further include some of the pixels, which respectively display white, cyan, and magenta.

Each of the pixels PX includes an organic light-emitting diode and a driving circuit GDC connected thereto. The driving circuit GDC and signal lines SGL may be included in a circuit element layer DP-CL illustrated in FIG. 5A.

The driving circuit GDC may include a scan driving circuit. The scan driving circuit generates a plurality of scan signals (hereinafter, scan signals) and sequentially outputs the scan signals to a plurality of scan lines GL (hereinafter, scan lines) which will be described later. The scan driving circuit may further output another control signal to the driving circuit of the pixels PX.

The scan driving circuit may include a plurality of thin film transistors formed through the same process as the driving circuit of the pixels PX, such as a low temperature polycrystaline silicon (LTPS) (process or a low temperature polycrystalline oxide (LTPO) process.

The signal lines SGL include scan lines GL, data lines DL, a power line PL, and a control signal line CSL. The scan lines GL are respectively connected to corresponding pixels PX among the pixels PX, and the data lines DL are respectively connected to corresponding pixels PX among the pixels PX. The power line PL is connected to the pixels PX. The control signal line CSL may provide control signals to the scan driving circuit.

The signal lines SGL overlap the display region DA and the non-display region NDA. The signal lines SGL may be respectively electrically connected to a plurality of panel pads disposed in the non-display region NDA. A region in the non-display region NDA, in which the plurality of panel pads are disposed, may be defined as a pad region PA (see FIG. 6). A detailed description of this will be provided later.

Depending on the types of the plurality of pixels PX, the display panel DP may be classified into a liquid crystal display panel, an organic electroluminescence light-emitting display panel, an electrowetting display panel, a quantum dot light-emitting display panel, etc. In this embodiment, the display panel DP may be an organic electroluminescence light-emitting display panel.

As illustrated in FIG. 5A, the display panel DP includes a panel base layer BL, a circuit element layer DP-CL disposed on the panel base layer BL, a display element layer DP-OLED, and an encapsulation layer TFL. In this specification, the phrase “a region/portion corresponds to another region/portion” means that “the two regions/portions overlap each other”, but the expression is not limited to having a same area and/or a same shape unless so specified.

The panel base layer BL may include at least one synthetic resin layer. The panel base layer BL may include a glass substrate, a metal substrate, or an organic/inorganic composite material substrate.

In the display panel DP according to an embodiment of the inventive concept, the panel base layer BL may be optically opaque. The panel base layer BL may include an optically opaque colored material. When the panel base layer BL includes a plurality of layers, at least some of the plurality of layers included in the panel base layer BL may include an optically opaque colored material.

The circuit element layer DP-CL includes at least one insulating layer and a circuit element. The insulating layer includes at least one inorganic layer and at least one organic layer. The circuit element includes signal lines, a pixel driving circuit, and the like.

The display element layer DP-OLED includes at least organic light-emitting diodes as a light-emitting element. The display element layer DP-OLED may further include an organic layer such as a pixel defining layer.

The encapsulation layer TFL includes a plurality of thin films. Some thin films are disposed to improve optical efficiency, and some other thin films are disposed to protect organic light-emitting diodes.

A black matrix (not illustrated) that blocks light may be disposed in the non-display region NDA. The driving circuit GDC may be provided in the non-display region NDA to supply a gate signal to a plurality of pixels PX. In an embodiment of the inventive concept, a data driving circuit (not illustrated) may be further provided in the non-display region NDA. A pad region PA (see FIG. 6) for receiving a signal supplied from the flexible printed circuit board CF may be defined in the mounting region MA.

As illustrated in FIGS. 4 and 5A, the flexible printed circuit board CF includes a flexible circuit board FPC and a data driving circuit DC. The data driving circuit DC may include at least one driving chip. The data driving circuit DC is electrically connected to the lines of the flexible circuit board FPC.

If the flexible printed circuit board CF includes the data driving circuit DC, the pad portion of the display panel DP may include data pads electrically connected to data lines and control signal pads electrically connected to control signal lines. The data lines may be connected to the pixels PX, and the control signal lines may be connected to the driving circuit GDC. In this embodiment, the flexible printed circuit board CF is illustrated to have a chip-on-film structure, but is not limited thereto.

The main circuit board MB provides image data, control signals, power voltage and the like to the display panel DP or the data driving circuit DC. The main circuit board MB is a wiring board larger than the flexible circuit board FPC and may include active and passive elements. The main circuit board MB is a flexible wiring board or a rigid wiring board and may include a pad portion (not illustrated) connected to the flexible circuit board FPC.

FIG. 5B is a cross-sectional view of a portion of the display module according to an embodiment of the inventive concept. FIG. 5B is an exploded cross-sectional view taken along line V-V′ of FIG. 5A.

Referring to FIGS. 5A and 5B, the flexible circuit board FPC may include a plurality of circuit pads FPD. In an embodiment of the inventive concept, the flexible circuit board FPC may include a circuit base layer BL-F and a plurality of circuit pads FPD disposed on the circuit base layer BL-F. The plurality of circuit pads FPD may be disposed on a surface of the circuit base layer BL-F spaced apart from each other by a predetermined distance. The circuit base layer BL-F provides a base to the flexible circuit board FPC disposed on the display panel DP. The circuit base layer BL-F may include a flexible material. For example, the circuit base layer BL-F may be a polyimide film having flexible properties.

The circuit base layer BL-F may be optically transparent. The circuit base layer BL-F may include an optically transparent material. In an embodiment of the inventive concept, the circuit base layer BL-F may include a transparent polyimide film.

The plurality of circuit pads FPD may be in direct contact with the pad region PA (see FIG. 6) of the display panel DP. Specifically, the plurality of circuit pads FPD may be in contact with panel pads PPD included in the circuit element layer of the display panel. As the plurality of circuit pads FPD and the panel pads PPD are in connect with each other, the flexible circuit board FPC and the display panel DP may be electrically connected to each other.

A conductive adhesive film ACF may be disposed between the flexible circuit board FPC and the display panel DP. The conductive adhesive film ACF may be disposed between the flexible circuit board FPC and the circuit element layer DP-CL in the pad region PA. The conductive adhesive film ACF may include a plurality of conductive balls CB that electrically connect the flexible circuit board FPC to the display panel DP. The conductive adhesive film ACF may further include adhesive resin BR in which the plurality of conductive balls CB are dispersed. The plurality of conductive balls CB may be aligned with each other in the second direction DR2 when the display panel DP and the flexible printed circuit board CF are electrically connected to each other.

FIG. 5C is a cross-sectional view of a display panel according to an embodiment of the inventive concept. FIG. 5C is a cross-sectional view taken along line O-O′ of FIG. 4.

FIG. 5C illustrates a cross-sectional view of the display region DA of the display panel DP. Referring to FIG. 5C, the display panel DP may include a buffer layer BFL, a first gate insulating layer GI1, a second gate insulating layer GI2, an interlayer insulating layer ILD, an upper insulating layer VIA1, a semiconductor pattern ACP including a plurality of patterns, a first conductive layer CLP1 including a plurality of patterns, a second conductive layer CLP2 including a plurality of patterns, and a third conductive layer CLP3 including a plurality of patterns. Here, the first conductive layer CLP1 may include a first gate metal pattern, the second conductive layer CLP2 may include a second gate metal pattern, and the third conductive layer CLP3 may include a first data metal pattern.

In an embodiment of the inventive concept, each of the first gate insulating layer GI1, the second gate insulating layer GI2, and the interlayer insulating layer ILD includes an organic film and/or an inorganic film. In an embodiment of the inventive concept, each of the first gate insulating layer GI1, the second gate insulating layer GI2, and a first insulating layer ILD1 may include a plurality of inorganic thin films. The plurality of inorganic thin films may include a silicon nitride layer and a silicon oxide layer. In an embodiment of the inventive concept, each of the first conductive layer CLP1 and the second conductive layer CLP2 may include molybdenum (Mo), but is not limited thereto.

In an embodiment of the inventive concept, the third conductive layer CLP3 may include at least one of aluminum (Al) or titanium (Ti), but is not limited thereto. In an embodiment of the inventive concept, the third conductive layer CLP3 may have a structure in which titanium, aluminum, and titanium are stacked in that order.

The buffer layer BFL may be disposed on the panel base layer BL. The buffer layer BFL may include a first buffer layer and a second buffer layer. The second buffer layer may be disposed on the first buffer layer. The buffer layer BFL prevents impurities present in the panel base layer BL from flowing into the pixel PX. In particular, the buffer layer BFL prevents impurities from diffusing into the semiconductor pattern ACP of transistors T1 and T2 constituting the pixel PX.

Impurities may be introduced from the outside or generated due to thermal decomposition of the panel base layer BL. The impurities may be gas or sodium discharged from the panel base layer BL. In addition, the buffer layer BFL may block moisture from being introduced into the pixel PX from the outside.

A semiconductor pattern ACP is disposed on the buffer layer BFL. In an embodiment of the inventive concept, the semiconductor pattern ACP may be disposed on the buffer layer BFL.

The semiconductor pattern ACP may constitute each of the transistors T1 and T2. The semiconductor pattern ACP may include polysilicon, amorphous silicon, or metal oxide semiconductor. FIG. 5C illustrates a semiconductor pattern constituting a source S1, an active C1, and a drain D1 of a first transistor T1 and a semiconductor pattern constituting a source S2, an active C2, and a drain D2 of a second transistor T2.

The first gate insulating layer GI1 may be disposed on the buffer layer BFL and cover the semiconductor pattern ACP. The first conductive layer CLP1 may be disposed on the first gate insulating layer GI1. The gate G1 of the first transistor T1 and the gate G2 of the second transistor T2 are illustrated in the first conductive layer CLP1. Although not separately illustrated, in an embodiment of the inventive concept, the first conductive layer CLP1 may include any one of two electrodes constituting a capacitor of the pixel PX.

The second gate insulating layer GI2 may be disposed on the first gate insulating layer GI1 and cover the first conductive layer CLP1. The second conductive layer CLP2 may be disposed on the second gate insulating layer GI2. In an embodiment of the inventive concept, the second conductive layer CLP2 may be the other one of the two electrodes constituting the capacitor CP of the pixel PX. An upper electrode UE is illustrated as the second conductive layer CLP2. An opening UE-OP may be defined in the upper electrode UE.

The interlayer insulating layer ILD may be disposed on the second gate insulating layer GI2 and cover the second conductive layer CLP2. First connection electrodes CNE-D1 of the first conductive layer CLP1 may be respectively connected to the gate G1 of the first transistor T1 and the source S2 of the second transistor T2. The upper insulating layer VIA1 may be disposed on the interlayer insulating layer ILD and cover the third conductive layer CLP3.

In FIG. 5C, a light-emitting element layer ELL in the display region DA may include a light-emitting element ED and a pixel defining layer PDL. The light-emitting element ED may include an anode electrode AE, a light-emitting layer EML, and a cathode electrode CE.

The anode electrode AE may be disposed on the upper insulating layer VIA1. The anode electrode AE may be electrically connected to the third conductive layer CLP3 through a contact hole. The pixel defining layer PDL may be disposed on the upper insulating layer VIA1 and expose at least a portion of the anode electrode AE. The light-emitting layer EML may be disposed on the anode electrode AE. The cathode electrode CE may be disposed on the light-emitting layer EML.

When the light-emitting element ED is an organic light-emitting diode (OLED), the light-emitting layer EML may include an organic material. The encapsulation layer TFL may seal the light-emitting element layer ELL to protect the light-emitting element layer ELL from external oxygen or moisture. The encapsulation layer TFL may be a layer in which an organic film and an inorganic film are mixed with each other.

FIG. 6 is a plan view of a partial region of the display module according to an embodiment of the inventive concept. FIG. 6 is an exploded plan view illustrating an enlarged region AA of FIG. 4.

Referring to FIGS. 4 to 6 together, a pad region PA may be defined in the display panel DP. The pad region PA is defined in a portion of the mounting region MA and may be a region in which a plurality of panel pads PPD are disposed.

A substrate pad region PA-CF of the flexible circuit board FPC of the flexible printed circuit board CF and the pad region PA of the display panel DP may be electrically connected to each other by a conductive adhesive film ACF. Although not illustrated, the pad portion of the main circuit board MB may include pads electrically connected to the circuit pads FPD of the flexible circuit board FPC. The input pad portion of the flexible circuit board FPC and the pad portion of the main circuit board MB may also be electrically connected to each other by the conductive adhesive film ACF. The conductive adhesive film ACF may be an anisotropic conductive film ACF. In an embodiment of the inventive concept, a shoulder bump may replace the conductive adhesive film ACF. The circuit pads FPD disposed in the substrate pad region PA-CF of the flexible circuit board FPC may be electrically connected to the panel pads PPD disposed in the pad region PA of the display panel DP by the conductive adhesive film ACF. The conductive adhesive film ACF may include a plurality of conductive balls CB. When the conductive adhesive film ACF is disposed between the flexible circuit board FPC and the display panel DP, the plurality of conductive balls CB aligned in the first direction may electrically connect the circuit pads FPD of the flexible circuit board FPC and the panel pads PPD of the display panel DP to each other.

The flexible circuit board FPC included in the flexible printed circuit board CF according to an embodiment of the inventive concept includes a plurality of circuit pads FPD and circuit lines FCL connected to at least some of the circuit pads FPD. The plurality of circuit pads FPD may be disposed in the substrate pad region PA-CF. The plurality of circuit pads FPD may be disposed on the circuit base layer BL-F of the flexible circuit board FPC. Meanwhile, in FIG. 6, for the convenience of explanation, components such as the plurality of circuit pads FPD included in the flexible printed circuit board CF are illustrated with solid lines, but the components included in the flexible printed circuit board CF may be disposed on the rear surface of the circuit base layer BL-F.

Although not illustrated, at least some of the plurality of circuit pads FPD may be electrically connected to the data driving circuit DC included in the flexible printed circuit board CF through the circuit lines FCL.

The plurality of circuit pads FPD of the flexible circuit board FPC include a plurality of functional pads FFD and a circuit alignment pad F-AM. The circuit lines FCL may be connected to the plurality of functional pads FFD.

The plurality of functional pads FFD may be disposed to be spaced apart from each other at a predetermined distance. The plurality of functional pads FFD may be connected to the pad region PA of the display panel DP. Specifically, the plurality of functional pads FFD may be connected to display pads DPD of the display panel DP, which will be described later. As the plurality of functional pads FFD and display pads DPD are connected to each other, the flexible circuit board FPC and the display panel DP may be electrically connected to each other.

The circuit alignment pad F-AM may have a shape that at least partially overlaps the substrate pad region PA-CF. At least a portion of the circuit alignment pad F-AM may overlap the plurality of functional pads FFD in the second direction DR2. In the process of bonding the flexible circuit board FPC to the display panel DP, the circuit alignment pad F-AM may be used to determine the position of the flexible circuit board FPC or applied as an identification mark to align the flexible circuit board FPC and the display panel DP.

A separation portion SPP is defined in the circuit alignment pad F-AM. In the display device according to an embodiment of the inventive concept, the alignment state of the flexible circuit board FPC and the display panel DP may be measured according to the positions of the separation portion SPP defined in the circuit alignment pad F-AM and a panel alignment pad P-AM which will be described later.

The display panel DP according to an embodiment of the inventive concept includes a plurality of panel pads PPD and signal lines SGL connected to at least some of the panel pads PPD. The plurality of panel pads PPD may be disposed on the panel base layer BL of the display panel DP. The plurality of panel pads PPD may be disposed in the pad region PA of the display panel DP.

The plurality of panel pads PPD include a plurality of display pads DPD and a panel alignment pad P-AM. The signal lines SGL may be connected to the plurality of display pads DPD.

The plurality of display pads DPD may have a shape corresponding to the functional pads FFD included in the flexible circuit board FPC. That is, the extension direction of the plurality of display pads DPD may be the same as the extension direction of the functional pads FFD. The signal lines SGL may be connected to the plurality of display pads DPD. For example, the data lines DL or the control signal line CSL described above may be connected to the plurality of display pads DPD.

The panel alignment pad P-AM may be disposed in the pad region PA of the display panel DP. The panel alignment pad P-AM may correspond to the separated portion SPP defined in the circuit alignment pad F-AM. In the process of attaching the flexible circuit board FPC to the display panel DP, the panel alignment pad P-AM may be used to determine the position of the display panel DP or applied as an identification mark to align the display panel DP and the flexible circuit board FPC.

In a state in which the flexible circuit board FPC and the display panel DP according to an embodiment of the inventive concept are attached to each other, the panel alignment pad P-AM may overlap the separated portion SPP defined in the circuit alignment pad F-AM on a plane or be side by side therewith in the second direction DR2. In a state in which the flexible circuit board FPC and the display panel DP are bonded to each other, the panel alignment pad P-AM may overlap the circuit alignment pad F-AM in the first direction DR1 or the second direction DR2. As used herein, A and B “overlapping in the first direction” means A and B share a common coordinate along the second direction. Similarly, A and B “overlapping in the second direction” means A and B share a common coordinate along the first direction. The arrangement relationship between the panel alignment pad P-AM and the circuit alignment pad F-AM will be described in more detail later in the descriptions of FIGS. 7 to 13B.

FIG. 7 is an enlarged plan view of a partial region of the flexible circuit board FPC according to an embodiment of the inventive concept. FIG. 8 is an enlarged plan view of a partial region of the display panel according to an embodiment of the inventive concept. FIGS. 9A and 9B are plan views of a partial region of the display module according to an embodiment of the inventive concept. FIG. 7 illustrates the circuit pads and surrounding components of the flexible circuit board FPC illustrated in FIG. 6. FIG. 8 illustrates the display pads and surrounding components of the display panel illustrated in FIG. 6. FIG. 9A illustrates a plan view showing a state in which the display panel DP and the flexible circuit board FPC are coupled to each other in a region AA of FIG. 6. FIG. 9B illustrates an enlarged plan view of a portion of the display module illustrated in FIG. 9A.

Referring to FIGS. 4, 6, and 7 together, the flexible circuit board FPC according to an embodiment of the inventive concept includes a plurality of circuit pads FPD and circuit lines FCL connected to at least some of the circuit pads. The plurality of circuit pads FPD may be disposed in the substrate pad region PA-CF. The plurality of circuit pads FPD may be disposed on the circuit base layer BL-F of the flexible circuit board FPC. Meanwhile, in FIG. 7, for the convenience of explanation, components such as the plurality of circuit pads FPD included in the flexible circuit board FPC are illustrated with solid lines, but the components included in the flexible circuit board FPC may be disposed on the rear surface of the circuit base layer BL-F.

The plurality of circuit pads FPD include a plurality of functional pads FFD and a circuit alignment pad F-AM. The circuit lines FCL may be connected to the plurality of functional pads FFD.

The plurality of functional pads FFD may have a shape corresponding to the plurality of display pads DPD included in the display panel DP. The plurality of functional pads FFD may extend in the first direction DR1 and be arranged in the second direction DR2. The plurality of functional pads FFD may be disposed to be spaced apart from each other in the second direction DR2. The plurality of functional pads FFD may have a bar shape extending in the first direction DR1. The plurality of circuit lines FCL connected to the plurality of functional pads FFD may also extend in the first direction DR1.

The circuit alignment pad F-AM extends in the first direction DR1 and is disposed to be spaced apart from the plurality of functional pads FFD in the second direction DR2. The circuit alignment pad F-AM may have a bar shape extending in the first direction DR1. At least a portion of the circuit alignment pad F-AM may overlap the plurality of functional pads FFD in the second direction DR2. In the embodiment illustrated in FIG. 7, the circuit alignment pad F-AM may be provided in plurality.

The circuit alignment pad F-AM according to an embodiment of the inventive concept may include a first outer circuit alignment pad OPP1 and a main circuit alignment pad CPP that are spaced apart from each other in the second direction DR2. Each of the first outer circuit alignment pad OPP1 and the main circuit alignment pad CPP may extend in the first direction DR1. The main circuit alignment pad CPP may be disposed on one side of the first outer circuit alignment pad OPP1. The main circuit alignment pad CPP may be spaced apart from the plurality of functional pads FFD in the second direction DR2 with the first outer circuit alignment pad OPP1 interposed therebetween.

A separated portion SPP may be defined in at least one of the circuit alignment pads F-AM. As in an embodiment of the inventive concept, the separated portion SPP may be defined in the main circuit alignment pad CPP. The main circuit alignment pad CPP may include a first portion P1 and a second portion P2 spaced apart from each other in the first direction DR1, and the separated portion SPP may be defined between the first portion P1 and the second portion P2.

The plurality of circuit pads FPD may include left circuit pads arranged on the left side of the flexible circuit board FPC based on a center line CTL, which is defined in the center of the flexible circuit board FPC in the second direction DR2 and crosses in the first direction DR1, and right circuit pads arranged on the right side of the flexible circuit board FPC based on the center line CTL. The left circuit pads and the right circuit pads may be arranged to be symmetrical to each other with respect to the center line CTL.

The left and right circuit pads may respectively include the above-described circuit alignment pads F-AM1 and F-AM2. The left circuit pads may include a plurality of first functional pads FFD1 extending in the first direction DR1 and a first circuit alignment pad F-AM1 spaced apart from the plurality of first functional pads FFD1 in the second direction DR2. The right circuit pads may include a plurality of second functional pads FFD2 extending in the first direction DR1 and a second circuit alignment pad F-AM2 spaced apart from the plurality of second functional pads FFD2 in the second direction DR2. The first circuit alignment pad F-AM1 may include a (1-1)-th outer circuit alignment pad OPP1-1 and a first main circuit alignment pad CPP1 that are spaced apart from each other in the second direction DR2. The second circuit alignment pad F-AM2 may include a (1-2)-th outer circuit alignment pad OPP1-2 and a second main circuit alignment pad CPP2 that are spaced apart from each other in the second direction DR2.

Separated portions SPP1 and SPP2 may be respectively defined in the first circuit alignment pad F-AM1 and the second circuit alignment pad F-AM2. As in an embodiment of the inventive concept, the separated portions SPP1 and SPP2 may be respectively defined in the first main circuit alignment pad CPP1 and the second main circuit alignment pad CPP2. The first main circuit alignment pad CPP1 may include a (1-1)-th portion P1-1 and a (2-1)-th portion P2-1 that are spaced apart from each other in the second direction DR2, and a first separated portion SPP1 may be defined between the (1-1)-th portion P1-1 and the (2-1)-th portion P2-1. The second main circuit alignment pad CPP2 may include a (1-2)-th portion P1-2 and a (2-2)-th portion P2-2 that are spaced apart from each other in the second direction DR2, and a second separated portion SPP2 may be defined between the (1-2)-th portion P1-2 and the (2-2)-th portion P2-2.

Referring to FIGS. 4, 6, and 8 together, the display panel DP according to an embodiment of the inventive concept includes a plurality of panel pads PPD. The plurality of panel pads PPD may be disposed on the panel base layer BL of the display panel DP. The plurality of panel pads PPD may be disposed in the pad region PA of the display panel DP.

The plurality of panel pads PPD include a plurality of display pads DPD and a panel alignment pad P-AM. The signal lines SGL may be connected to the plurality of display pads DPD.

The plurality of display pads DPD may have a shape corresponding to the functional pads FFD included in the flexible circuit board FPC. The plurality of display pads DPD may extend in the first direction DR1 and be arranged in the second direction DR2. That is, the extension direction of the plurality of display pads DPD may be the same as the extension direction of the functional pads FFD. The signal lines SGL, such as data lines DL or a control signal line CSL, may be connected to the plurality of display pads DPD, and the extension direction of the signal lines SGL may also be the first direction DR1.

The panel alignment pad P-AM may be disposed to be spaced apart from the plurality of display pads DPD in the second direction DR2. The panel alignment pad P-AM may overlap the plurality of display pads DPD in the second direction DR2. The panel alignment pad P-AM may correspond to the separated portion SPP defined in the circuit alignment pad F-AM. In a state in which the display panel DP and the flexible circuit board FPC are coupled to each other, the panel alignment pad P-AM is disposed to avoid overlapping the circuit alignment pad F-AM.

A panel center line CTL corresponding to the center line CTL defined in the flexible circuit board FPC may be defined in the display panel DP. The plurality of panel pads PPD may include left panel pads arranged on the left side of the display panel DP based on the panel center line CTL and right panel pads arranged on the right side of the display panel DP based on the panel center line CTL. The left panel pads and the right panel pads may be arranged to be symmetrical to each other with respect to the panel center line CTL.

The left and right panel pads may respectively include the panel alignment pads P-AM1 and P-AM2 described above. The left panel pads may include a plurality of first display pads DPD1 extending in the first direction DR1 and a left panel alignment pad P-AM1 spaced apart from the plurality of first display pads DPD1 in the second direction DR2. The right panel pads may include a plurality of second display pads DPD2 extending in the first direction DR1 and a right panel alignment pad P-AM2 spaced apart from the plurality of second display pads DPD2 in the second direction DR2. The left panel alignment pad P-AM1 and the right panel alignment pad P-AM2 may be disposed to respectively correspond to the above-described separated portions SPP1 and SPP2.

Meanwhile, the plurality of panel pads PPD may further include a dummy pad MPD. The dummy pad MPD may be an electrically floated pad that does not substantially provide a signal. The dummy pad MPD may not be connected to a signal line SGL. The dummy pad MPD may extend in the first direction DR1 like the display pads DPD and be spaced apart from the display pads DPD in the second direction DR2. The dummy pad MPD may overlap the display pads DPD in the second direction DR2. The dummy pad MPD may correspond to one of the circuit alignment pads F-AM of the flexible circuit board FPC. As in an embodiment of the inventive concept, the dummy pad MPD may correspond to the first outer circuit alignment pad OPP1 of the circuit alignment pad F-AM.

Referring to FIGS. 6 to 9A and 9B together, in a state in which the display panel DP and the flexible circuit board FPC according to an embodiment of the inventive concept are coupled to each other by the conductive adhesive film ACF, the plurality of display pads DPD and the plurality of functional pads FFD included in the flexible circuit board FPC may be disposed at corresponding positions. The plurality of conductive balls CB (see FIG. 5B) included in the above-described conductive adhesive film ACF may be interposed between the plurality of display pads DPD and the plurality of functional pads FFD and electrically connect the plurality of display pads DPD and the plurality of functional pads FFD to each other.

As illustrated in FIGS. 9A and 9B, in a state in which the display panel DP and the flexible circuit board FPC according to an embodiment of the inventive concept are coupled to each other by the conductive adhesive film ACF, the panel alignment pads P-AM1 and P-AM2 included in the display panel DP may be disposed to correspond to the separated portions SPP1 and SPP2 defined in the circuit alignment pads F-AM1 and F-AM2 included in the flexible circuit board FPC. The panel alignment pads P-AM1 and P-AM2 may be disposed to avoid overlapping the circuit alignment pads F-AM1 and F-AM2 on a plane.

The panel alignment pads P-AM1 and P-AM2 may be disposed within the separated portions SPP1 and SPP2 defined in the circuit alignment pads F-AM1 and F-AM2. The panel alignment pads P-AM1 and P-AM2 may overlap any one of the circuit alignment pads F-AM1 and F-AM2 in the first direction DR1. As in an embodiment of the inventive concept, the circuit alignment pads F-AM1 and F-AM2 may include the main circuit alignment pads CPP1 and CPP2 in which the separated portions SPP1 and SPP2 are defined, and the panel alignment pads P-AM1 and P-AM2 may be disposed in the separated portions SPP1 and SPP2 defined in the main circuit alignment pads CPP1 and CPP2. The panel alignment pads P-AM1 and P-AM2 may overlap the main circuit alignment pads CPP1 and CPP2 in the first direction DR1.

As illustrated in FIGS. 9A and 9B, the panel alignment pad P-AM may be disposed in the center of the separated portion SPP. In an embodiment of the inventive concept, the first portion P1 and the second portion P2 may be spaced apart from each other by a first distance d1 in the first direction DR1, and the first distance d1 may be greater than a second distance d2 which is the width of the panel alignment pad P-AM in the first direction DR1. In an embodiment of the inventive concept, the first distance d1 may be 2 to 4 times the second distance d2. In one embodiment, the first distance d1 may be about 200 micrometers to about 400 micrometers. In one embodiment, the second distance d2 may be about 70 micrometers to about 130 micrometers.

The separation distance between the first portion P1 and the panel alignment pad P-AM in the first direction DR1 is a third distance d3, and the separation distance between the second portion P2 and the panel alignment pad P-AM in the first direction DR1 is a fourth distance d4, and the third distance d3 and the fourth distance d4 may be substantially the same as each other. Meanwhile, in this specification, the expression “substantially the same” includes not only a case in which distances and widths are physically completely the same as each other, but also a case in which there is a difference equal to a tolerance that may occur during a process despite a same design. In an embodiment of the inventive concept, each of the third distance d3 and the fourth distance d4 may be about 70 micrometers to about 130 micrometers.

The panel alignment pad P-AM disposed in the separated portion SPP may have a bar shape extending in the first direction DR1, or may have a rectangular shape with sides having similar lengths and extending in each of the first direction DR1 and the second direction DR2. The panel alignment pad P-AM according to an embodiment of the inventive concept does not include a protruding portion extending from the main body in the first direction DR1 or the second direction DR2.

The panel alignment pad P-AM may have a first width w1 in the second direction DR2. The main circuit alignment pad CPP having the separated portion SPP which is defined therein and in which the panel alignment pad P-AM is disposed may have the same first width w1 in the second direction DR2. That is, the panel alignment pad P-AM and the main circuit alignment pad CPP may have substantially the same width as each other in the second direction DR2. The first width w1 may be, for example, about 70 micrometers to about 130 micrometers.

The main circuit alignment pad CPP may be wider in the second direction DR2 than the first outer circuit alignment pad OPP1. In an embodiment of the inventive concept, the first outer circuit alignment pad OPP1 has a second width w2, and the first width w1 of the main circuit alignment pad CPP may be greater than the second width w2.

Meanwhile, FIGS. 9A and 9B exemplarily illustrate that the panel alignment pad P-AM has a square shape on a plane, but this shape is not a limitation. The panel alignment pad P-AM may have any shape as long as the alignment state of the display panel DP and the flexible circuit board FPC can be determined. For example, the panel alignment pad P-AM may have a polygonal shape such as a rectangle, a triangle, or a pentagon, or a square shape with rounded corners. Alternatively, the panel alignment pad P-AM may have a circular or oval shape.

In the display device according to an embodiment of the inventive concept, in a state in which the display panel DP and the flexible circuit board FPC are coupled to each other, the panel alignment pad P-AM may correspond to the separated portion SPP defined in the circuit alignment pad F-AM, and the panel alignment pad P-AM and the circuit alignment pad F-AM may be disposed to avoid overlapping each other. Accordingly, problems such as a bending or layer lifting phenomenon in the flexible circuit board FPC may be prevented from occurring in the process of bonding the flexible circuit board FPC and the display panel DP to each other, and although the panel base layer BL included in the display panel DP is optically opaque, the alignment state of the display panel DP and the flexible circuit board FPC may be checked from the side of the flexible circuit board FPC. Accordingly, the durability and reliability of the display device may be improved.

Unlike the display device according to an embodiment of the inventive concept, when the panel alignment pad and the circuit alignment pad overlap each other on a plane in a state in which the display panel DP and the flexible circuit board FPC are coupled to each other, defects such as a bending or layer lifting phenomenon may occur due to the flexible circuit board FPC at a portion at which the panel alignment pad and the circuit alignment pad overlap each other during a pressing process. In addition, when a bending phenomenon occurs in the flexible circuit board FPC, it becomes difficult to determine the alignment state of the display panel and the flexible circuit board FPC from the side of the flexible circuit board FPC, thus making it difficult to check the alignment state after a pressing process of the display panel DP and the flexible circuit board FPC. In the display device according to an embodiment of the inventive concept, as the panel alignment pad P-AM is disposed to correspond to the separation portion SPP defined in the circuit alignment pad F-AM, it is possible to prevent the flexible circuit board FPC from being bent or prevent the circuit alignment pad F-AM and the panel alignment pad P-AM from being deformed due to the shapes of the circuit alignment pad F-AM and the panel alignment pad P-AM in the process of bonding the flexible circuit board FPC and the display panel DP to each other. In addition, it is possible to prevent problems such as a lifting phenomenon of a layer included in the flexible circuit board FPC and check the alignment state of the display panel DP and the flexible circuit board FPC from above the flexible circuit board FPC. Accordingly, the durability and reliability of the display device may be improved.

Meanwhile, in the display device according to an embodiment of the inventive concept, while the circuit alignment pad F-AM included in the flexible circuit board FPC has a bar shape extending in the first direction DR1, the first portion P1 and the second portion P2 may be formed to be spaced apart from each other in the first direction DR1 with respect to the separation portion SPP to which the panel alignment pad P-AM is disposed to correspond.

Unlike the display device according to an embodiment of the inventive concept, when the circuit alignment pad F-AM in which the separated portion SPP is formed does not have a bar shape extending in the first direction DR1, that is, when the circuit alignment pad F-AM has a curved shape with a protruding portion in a different direction (for example, the second direction DR2) such as a cross or boomerang rather than a bar shape, it becomes difficult to determine the alignment state of the alignment pads, thus making it difficult to check the alignment state after the display panel DP and the flexible circuit board FPC are placed in contact or combined. More specifically, when the circuit alignment pad F-AM having a curved shape is included in the flexible circuit board FPC, a significant bending phenomenon may occur due to the flexible circuit board FC being pressed against the display panel DP for coupling and thus, it may become difficult to check the alignment state of the display panel DP and the flexible circuit board FPC from above the flexible circuit board FPC. As the display device according to an embodiment of the inventive concept includes the circuit alignment pad F-AM including the separation portion SPP having a shape that is spaced apart in the first direction DR1 as well as having a bar shape extending in the first direction DR1, the degree of bending of the flexible circuit board FPC is reduced during the pressing process, and thus it is possible to determine the alignment state of the display panel DP and the flexible circuit board FPC more accurately. Accordingly, the durability and reliability of the display device may be improved.

FIG. 10 is an enlarged plan view of a partial region of a flexible circuit board FPC according to an embodiment of the inventive concept. FIG. 10 is an enlarged plan view of a partial region of a flexible circuit board FPC according to another embodiment of the inventive concept, which is different from the flexible circuit board such as what is illustrated in FIG. 7.

Referring to FIG. 10, the circuit alignment pad F-AM according to an embodiment of the inventive concept may include a first outer circuit alignment pad OPP1, a main circuit alignment pad CPP, and a second outer circuit alignment pad OPP2 which are spaced apart from each other in the second direction DR2. The embodiment illustrated in FIG. 10 differs from the embodiment illustrated in FIG. 7 in that the circuit alignment pad F-AM further includes the second outer circuit alignment pad OPP2. The main circuit alignment pad CPP may be disposed between the first outer circuit alignment pad OPP1 and the second outer circuit alignment pad OPP2.

The circuit alignment pad F-AM included in each of the left and right circuit pads may include the first outer circuit alignment pad OPP1 and the second outer circuit alignment pad OPP2. The left circuit pads may include a plurality of first functional pads FFD1 extending in the first direction DR1 and a first circuit alignment pad F-AM1 spaced apart from the plurality of first functional pads FFD1 in the second direction DR2. The right circuit pads may include a plurality of second functional pads FFD2 extending in the first direction DR1 and a second circuit alignment pad F-AM2 spaced apart from the plurality of second functional pads FFD2 in the second direction DR2. The first circuit alignment pad F-AM1 may include a (1-1)-th outer circuit alignment pad OPP1-1, a first main circuit alignment pad CPP1, and a (2-1)-th outer circuit alignment pad OPP2-1 which are spaced apart from each other in the second direction DR2. The second circuit alignment pad F-AM2 may include a (1-2)-th outer circuit alignment pad OPP1-2, a second main circuit alignment pad CPP2, and a (2-2)-th outer circuit alignment pad OPP2-2 which are spaced apart from each other in the second direction DR2. The first main circuit alignment pad CPP1 may be disposed between the (1-1)-th outer circuit alignment pad OPP1-1 and the (2-1)-th outer circuit alignment pad OPP2-1. The second main circuit alignment pad CPP2 may be disposed between the (1-2)-th outer circuit alignment pad OPP1-2 and the (2-2)-th outer circuit alignment pad OPP2-2. In some embodiments, the first set of components (e.g., FFD1, OPP1-1, CPP1, SPP1, OPP2-1) and the second set of components (e.g., FFD2, OPP1-2, CPP2, SP2, OPP2-2) of the flexible circuit board FPC may be arranged symmetrically with respect to the center line CTL.

FIG. 11 is an enlarged plan view of a partial region of a flexible circuit board FPC according to an embodiment of the inventive concept. FIG. 12 is an enlarged plan view of a partial region of a display panel DP according to an embodiment of the inventive concept. FIGS. 13A and 13B are plan views of a partial region of a display module including the flexible circuit board FPC and the display panel DP according to an embodiment of the inventive concept. FIGS. 11 to 13B respectively illustrate a flexible circuit board FPC, a display panel, and a display module according to another embodiment of the inventive concept, which are different from the flexible circuit board FPC, the display panel, and the display module according to an embodiment of the inventive concept, which are illustrated in FIGS. 7 to 9B.

Referring to FIGS. 4 and 11 together, the flexible circuit board FPC according to an embodiment of the inventive concept includes a plurality of circuit pads FPD (see FIG. 5B) and circuit lines FCL connected to at least some of the circuit pads FPD. The plurality of circuit pads FPD may be disposed on the circuit base layer BL-F of the flexible circuit board FPC. Meanwhile, in FIG. 11, for the convenience of explanation, components such as the plurality of circuit pads FPD included in the flexible circuit board FPC are illustrated with solid lines, but the components included in the flexible circuit board FPC may be disposed on the rear surface of the circuit base layer BL-F.

The plurality of circuit pads FPD include a plurality of functional pads FFD and a circuit alignment pad F-AM. The circuit lines FCL may be connected to the plurality of functional pads FFD.

The plurality of functional pads FFD may have a shape corresponding to the plurality of display pads DPD included in the display panel DP. The plurality of functional pads FFD may extend in the first direction DR1 and be arranged in the second direction DR2. The plurality of functional pads FFD may be disposed to be spaced apart from each other in the second direction DR2. The plurality of functional pads FFD may have a bar shape extending in the first direction DR1. The plurality of circuit lines FCL connected to the plurality of functional pads FFD may also extend in the first direction DR1.

The circuit alignment pad F-AM extends in the first direction DR1 and is disposed to be spaced apart from the plurality of functional pads FFD in the second direction DR2. At least a portion of the circuit alignment pad F-AM may overlap the plurality of functional pads FFD in the second direction DR2.

A separated portion SPP may be defined in the circuit alignment pad F-AM. As in an embodiment of the inventive concept, the circuit alignment pad F-AM may include a first portion P1 and a second portion P2 spaced apart from each other in the second direction DR2, and the separated portion SPP may be defined between the first portion P1 and the second portion P2.

The plurality of circuit pads FPD may include left circuit pads arranged on the left side of the flexible circuit board FPC based on a center line, which is defined in the center of the flexible circuit board FPC in the second direction DR2 and crosses in the first direction DR1, and right circuit pads arranged on the right side of the flexible circuit board FPC based on the center line CTL. The left circuit pads and the right circuit pads may be arranged to be symmetrical to each other with respect to the center line CTL.

The left and right circuit pads may respectively include the circuit alignment pads F-AM1 and F-AM2 described above. The left circuit pads may include a plurality of first functional pads FFD1 extending in the first direction DR1 and a first circuit alignment pad F-AM1 spaced apart from the plurality of first functional pads FFD1. The right circuit pads may include a plurality of second functional pads FFD2 extending in the first direction DR1 and a second circuit alignment pad F-AM2 spaced apart from the plurality of second functional pads FFD2 in the second direction DR2.

Separated portions SPP1 and SPP2 may be respectively defined in the first circuit alignment pad F-AM1 and the second circuit alignment pad F-AM2. The first circuit alignment pad F-AM1 may include a (1-1)-th portion P1-1 and a (2-1)-th portion P2-1 spaced apart from each other in the second direction DR2, and a first separated portion SPP1 defined between the (1-1)-th portion P1-1 and the (2-1)-th portion P2-1. The second circuit alignment pad F-AM2 may include a (1-2)-th portion P1-2 and a (2-2)-th portion P2-2 spaced apart from each other in the second direction DR2, and a second separated portion SPP2 defined between the (1-2)-th portion P1-2 and the (2-2)-th portion P2-2.

Referring to FIGS. 4 and 12 together, the display panel DP according to an embodiment of the inventive concept includes a plurality of panel pads PPD. The plurality of panel pads PPD may be disposed on the panel base layer BL of the display panel DP.

The plurality of panel pads PPD include a plurality of display pads DPD and a panel alignment pad P-AM. The signal lines SGL may be connected to the plurality of display pads DPD.

The plurality of display pads DPD may have a shape corresponding to the functional pads FFD included in the flexible circuit board FPC. The plurality of display pads DPD may extend in the first direction DR1 and be arranged in the second direction DR2. That is, the extension direction of the plurality of display pads DPD may be the same as the extension direction of the functional pads FFD.

The panel alignment pad P-AM may be disposed to be spaced apart from the plurality of display pads DPD in the second direction DR2. The panel alignment pad P-AM may overlap the plurality of display pads DPD in the second direction DR2. In a state in which the display panel DP and the flexible circuit board FPC are coupled to each other, the panel alignment pad P-AM is disposed to avoid overlapping the circuit alignment pad F-AM on a plane. The panel alignment pad P-AM may correspond to the separated portion SPP defined in the circuit alignment pad F-AM.

The panel alignment pad P-AM may be provided in plurality, and the plurality of panel alignment pads P-AM may be spaced apart from each other in the second direction DR2. The panel alignment pads P-AM may include a first panel alignment pad AM1 and a second panel alignment pad AM2 spaced apart from each other in the second direction DR2. Each of the first panel alignment pad AM1 and the second panel alignment pad AM2 may extend in the first direction DR1.

A panel center line CTL corresponding to the center line CTL defined in the flexible circuit board FPC may be defined in the display panel DP. The plurality of panel pads PPD may include left panel pads arranged on the left side of the display panel DP based on the panel center line CTL and right panel pads arranged on the right side of the display panel DP based on the panel center line CTL. The left panel pads and the right panel pads may be arranged to be symmetrical to each other with respect to the panel center line CTL.

The left and right panel pads may respectively include the panel alignment pads P-AM1 and P-AM2 described above. The left panel pads may include a plurality of first display pads DPD1 extending in the first direction DR1 and a left panel alignment pad P-AM1 spaced apart from the plurality of first display pads DPD1 in the second direction DR2. The left panel alignment pad P-AM1 may include a (1-1)-th panel alignment pad AM11 and a (2-1)-th panel alignment pad AM21, and the (1-1)-th panel alignment pad AM11 and the (2-1)-th panel alignment pad AM21 may be spaced apart from each other in the second direction DR2. Each of the (1-1)-th panel alignment pad AM11 and the (2-1)-th panel alignment pad AM21 may extend in the first direction DR1. The right panel pads may include a plurality of second display pads DPD2 extending in the first direction DR1 and a right panel alignment pad P-AM2 spaced apart from the plurality of second display pads DPD2 in the second direction DR2. The right panel alignment pad P-AM2 may include a (1-2)-th panel alignment pad AM12 and a (2-2)-th panel alignment pad AM22, and the (1-2)-th panel alignment pad AM12 and the (2-2)-th panel alignment pad AM22 may be spaced apart from each other in the second direction DR2. Each of the (1-2)-th panel alignment pad AM12 and the (2-2)-th panel alignment pad AM22 may extend in the first direction DR1. The left panel alignment pad P-AM1 and the right panel alignment pad P-AM2 may be disposed to respectively correspond to the separated portions SPP1 and SPP2 described above.

Referring to FIGS. 11 to 13A and 13B together, in a state in which the display panel DP and the flexible circuit board FPC according to an embodiment of the inventive portion are coupled to each other by the conductive adhesive film ACF, the plurality of display pads DPD and the plurality of functional pads FFD included in the flexible circuit board FPC may be disposed at corresponding positions. The plurality of conductive balls CB (see FIG. 5B) included in the above-described conductive adhesive film ACF may be interposed between the plurality of display pads DPD and the plurality of functional pads FFD and electrically connect the plurality of display pads DPD and the plurality of functional pads FFD to each other.

As illustrated in FIGS. 13A and 13B, in a state in which the display panel DP and the flexible circuit board FPC according to an embodiment of the inventive concept are coupled to each other by the conductive adhesive film ACF, the panel alignment pads P-AM1 and P-AM2 included in the display panel DP may be disposed to correspond to the separated portions SPP1 and SPP2 defined in the circuit alignment pads F-AM1 and F-AM2 included in the flexible circuit board FPC. The panel alignment pads P-AM1 and P-AM2 may be disposed to avoid overlapping the circuit alignment pads F-AM1 and F-AM2.

The panel alignment pads P-AM1 and P-AM2 may overlap any one of the circuit alignment pads F-AM1 and F-AM2 in the second direction DR2. The panel alignment pads P-AM1 and P-AM2 may be disposed to overlap the separated portions SPP1 and SPP2 defined in the circuit alignment pads F-AM1 and F-AM2 in the second direction DR2. The panel alignment pads P-AM1 and P-AM2 may include first panel alignment pads AM11 and AM12 and second panel alignment pads AM21 and AM22 spaced apart from each other in the second direction DR2, and the circuit alignment pads F-AM1 and F-AM2 may be disposed between the first panel alignment pads AM11 and AM12 and the second panel alignment pads AM21 and AM22 in the second direction DR2. In a state in which the display panel DP and the flexible circuit board FPC are coupled to each other, the first circuit alignment pad F-AM1 may be disposed between the (1-1)-th panel alignment pad AM11 and the (2-1)-th panel alignment pad AM21 in the second direction DR2, and the second circuit alignment pad F-AM2 may be disposed between the (1-2)-th panel alignment pad AM12 and the (2-2)-th panel alignment pad AM22 in the second direction DR2.

As illustrated in FIGS. 13A and 13B, the circuit alignment pad F-AM may be disposed in the center between the first panel alignment pad AM1 and the second panel alignment pad AM2 included in the panel alignment pad P-AM. That is, the distance between the first panel alignment pad AM1 and the circuit alignment pad F-AM in the second direction DR2 may be substantially the same as the distance between the second panel alignment pad AM2 and the circuit alignment pad F-AM in the second direction DR2.

Meanwhile, the separated portion SPP defined between the first portion P1 and the second portion P2 may be spaced apart from each other by a first distance h1 in the first direction DR1. Each of the first panel alignment pad AM1 and the second panel alignment pad AM2 included in the panel alignment pad P-AM may have a length equal to a second distance h2 in the first direction DR1, and the second distance h2 may be larger than the first distance h1.

The first panel alignment pad AM1 and the second panel alignment pad AM2 may have substantially the same length as each other in the first direction DR1. The first panel alignment pad AM1 and the second panel alignment pad AM2 may have substantially the same shape as each other. The first panel alignment pad AM1 and the second panel alignment pad AM2 may be arranged side by side with each other in the second direction DR2. The first panel alignment pad AM1 may have a first upper surface S1-1 and a first lower surface S2-1, and the second panel alignment pad AM2 may have a second upper surface S1-2 and a second lower surface S2-2. The first upper surface S1-1 may be aligned with the second upper surface S1-2 in the second direction DR2, and the first lower surface S2-1 may be aligned with the second lower surface S2-2 in the second direction DR2.

Meanwhile, for each of the first panel alignment pad AM1 and the second panel alignment pad AM2, when the distance between the end of the first portion P1 of the circuit alignment pad F-AM and the upper surfaces S1-1 and S1-2 in the first direction DR1 is defined as a third distance h3, and the distance between the end of the second portion P2 of the circuit alignment pad F-AM and the lower surfaces S2-1 and S2-2 in the first direction is defined as a fourth distance h4, the third distance h3 and the fourth distance h4 may be substantially the same as each other. That is, the panel alignment pad P-AM may be designed symmetrically so that the distance in the first direction DR1 from the separated portion SPP of the circuit alignment pad F-AM to the upper surfaces S1-1 and S1-2 and the distance in the first direction DR1 from the separated portion SPP of the circuit alignment pad F-AM to the lower surfaces S2-1 and S2-2 are substantially the same as each other.

In addition, a first separation distance SS1 between the first panel alignment pad AM1 and the circuit alignment pad F-AM in the second direction DR2 and a second separation distance SS2 between the second panel alignment pad AM2 and the circuit alignment pad F-AM in the second direction DR2 may be substantially the same as each other. That is, the first panel alignment pad AM1 and the second panel alignment pad AM2 may be designed symmetrically so that the separation distances in the second direction DR2 with respect to the circuit alignment pad F-AM are the same as each other.

FIG. 14 is an enlarged plan view of a partial region of a flexible circuit board FPC according to an embodiment of the inventive concept. FIG. 15 is an enlarged plan view of a partial region of a display panel DP according to an embodiment of the inventive concept. FIG. 16 is a plan view of a partial region of a display module including the flexible circuit board FPC and the display panel DP according to an embodiment of the inventive concept. FIGS. 14 to 16 respectively illustrate a flexible circuit board FPC, a display panel DP, and a display module according to another embodiment of the inventive concept, which are different from the flexible printed circuit board, the display panel, and the display module according to an embodiment of the inventive concept, which are illustrated in FIGS. 7 to 9A.

Referring to FIGS. 4 and 14 together, the flexible printed circuit board CF according to an embodiment of the inventive concept includes a plurality of circuit pads FPD (see FIG. 5B) and circuit lines FCL connected to at least some of the circuit pads FPD. The plurality of circuit pads FPD may be disposed on the circuit base layer BL-F of the flexible circuit board FPC. Meanwhile, in FIG. 14, for the convenience of explanation, components such as the plurality of circuit pads FPD included in the flexible circuit board FPC are illustrated with solid lines, but the components included in the flexible circuit board FPC may be disposed on the rear surface of the circuit base layer BL-F.

The plurality of circuit pads FPD include a plurality of functional pads FFD and a circuit alignment pad F-AM. The circuit lines FCL may be connected to the plurality of functional pads FFD.

The plurality of functional pads FFD may have a shape corresponding to the plurality of display pads DPD included in the display panel DP. The plurality of functional pads FFD may extend in the first direction DR1 and be arranged in the second direction DR2. The plurality of functional pads FFD may be arranged to be spaced apart from each other in the second direction DR2. The plurality of functional pads FFD may have a bar shape extending in the first direction DR1. The plurality of circuit lines FCL connected to the plurality of functional pads FFD may also extend in the first direction DR1.

The circuit alignment pad F-AM may be disposed to be spaced apart from the plurality of functional pads FFD in the first direction DR1 and the second direction DR2. The circuit alignment pad F-AM does not overlap the plurality of functional pads FFD in each of the first direction DR1 and the second direction DR2.

The plurality of circuit pads FPD may further include circuit dummy pads FDM1 and FDM2. The circuit dummy pads FDM1 and FDM2 may be electrically floated pads that do not substantially provide a signal. The circuit dummy pads FDM1 and FDM2 may overlap the plurality of functional pads FFD in the second direction DR2. At least some of the circuit dummy pads FDM1 and FDM2 may overlap the circuit alignment pad F-AM in the first direction DR1.

The plurality of circuit pads FPD may include left circuit pads arranged on the left side of the center line CTL of the flexible circuit board FPC. The center line CTL may be an imaginary line that extends in the first direction DR1 halfway between the two edges of the flexible circuit board FPC that extend in the first direction DR1. The circuit pads FPD may also include right circuit pads arranged on the right side of the center line CTL. The left circuit pads and the right circuit pads may be arranged to be symmetrical to each other with respect to the center line CTL.

The left and right circuit pads may respectively include the circuit alignment pads F-AM1 and F-AM2 described above. The left circuit pads may include a plurality of first functional pads FFD1 extending in the first direction DR1 and a first circuit alignment pad F-AM1 spaced apart from the plurality of first functional pads FFD1 in each of the first direction DR1 and the second direction DR2. The right circuit pads may include a plurality of second functional pads FFD2 extending in the first direction DR1 and a second circuit alignment pad F-AM2 spaced apart from the plurality of second functional pads FFD2 in each of the first direction DR1 and the second direction DR2.

Referring to FIGS. 4 and 15 together, the display panel DP according to an embodiment of the inventive concept includes a plurality of panel pads PPD. The plurality of panel pads PPD may be disposed on the panel base layer BL of the display panel DP.

The plurality of panel pads PPD include a plurality of display pads DPD and a panel alignment pad P-AM. The signal lines SGL may be connected to the plurality of display pads DPD.

The plurality of display pads DPD may have a shape corresponding to the functional pads FFD included in the flexible circuit board FPC. The plurality of display pads DPD may extend in the first direction DR1 and be arranged in the second direction DR2. That is, the extension direction of the plurality of display pads DPD may be the same as the extension direction of the functional pads FFD.

The panel alignment pad P-AM may be disposed spaced apart from the plurality of display pads DPD in the second direction DR2. The panel alignment pad P-AM may overlap the plurality of display pads DPD in the second direction DR2. In a state in which the display panel DP and the flexible circuit board FPC are coupled to each other, the panel alignment pad P-AM is disposed to avoid overlapping the circuit alignment pad F-AM.

A panel virtual center line PTL may be defined in the display panel DP, about halfway between the two edges that extend in the first direction DR1. The plurality of panel pads PPD may include left panel pads arranged on the left side of the panel center line PTL and right panel pads arranged to the right side of the panel virtual center line PTL. The left panel pads and the right panel pads may be arranged to be symmetrical to each other with respect to the panel center line PTL. When the display panel DP is combined with the flexible circuit board FPC, the virtual center line CTL and the panel virtual center line PTL may overlap. The center lines CTL and PTL are referred to as “virtual” because it is not necessary for there to be a physical marking of the line.

The left and right panel pads may respectively include the panel alignment pads P-AM1 and P-AM2 described above. The left panel pads may include a plurality of first display pads DPD1 extending in the first direction DR1 and a left panel alignment pad P-AM1 spaced apart from the plurality of first display pads DPD1 in the second direction DR2. The right panel pads may include a plurality of second display pads DPD2 extending in the first direction DR1 and a right panel alignment pad P-AM2 spaced apart from the plurality of second display pads DPD2 in the second direction DR2.

Referring to FIGS. 14 to 16 together, in a state in which the display panel DP and the flexible circuit board FPC according to an embodiment of the inventive concept are coupled to each other by the conductive adhesive film ACF, the plurality of display pads DPD and the plurality of functional pads FFD included in the flexible circuit board FPC may be disposed at corresponding positions. The plurality of conductive balls CB (see FIG. 5B) included in the above-described conductive adhesive film ACF may be interposed between the plurality of display pads DPD and the plurality of functional pads FFD and electrically connect the plurality of display pads DPD and the plurality of functional pads FFD to each other.

As illustrated in FIG. 16, in a state in which the display panel DP and the flexible circuit board FPC according to an embodiment of the inventive concept are coupled to each other by the conductive adhesive film ACF, the panel alignment pads P-AM1 and P-AM2 included in the display panel DP may not overlap the circuit alignment pads F-AM1 and F-AM2 included in the flexible circuit board FPC.

In addition, as illustrated in FIG. 16, the panel alignment pads P-AM1 and P-AM2 may not overlap the circuit base layer BL-F of the flexible circuit board FPC, and the circuit alignment pads F-AM1 and F-AM2 may not overlap the panel base layer BL of the display panel DP. That is, in a state in which the display panel DP and the flexible circuit board FPC are coupled according to an embodiment of the inventive concept by the conductive adhesive film ACF, the panel alignment pads P-AM1 and P-AM2 may be disposed in a region that would not be overlapped by the flexible circuit board FPC, and the circuit alignment pads F-AM1 and F-AM2 may be disposed in a region that would not be overlapped by the display panel DP.

FIG. 17 is a flowchart showing a method of manufacturing a display device according to an embodiment of the inventive concept. FIG. 18 is a cross-sectional view illustrating a stage in the method of manufacturing the display device according to an embodiment of the inventive concept. FIGS. 19A to 19C are plan views illustrating a sage in the method of manufacturing the display device according to an embodiment of the inventive concept.

Referring to FIG. 17, the method of manufacturing a display device according to an embodiment of the inventive concept includes preparing a display panel (S100), preparing a flexible printed circuit board (S200), combining the display panel and the flexible printed circuit board (S300), and determining or measuring the degree of alignment of the flexible circuit board in a combined state (S400). The measuring of the degree of alignment of the flexible printed circuit board in a combined (e.g., pressed) state (S400) includes measuring the distance in at least one direction between a circuit alignment pad included in the flexible printed circuit board and a panel alignment pad included in the display panel.

FIG. 18 illustrates a cross section during the measuring of the degree of alignment of the flexible printed circuit board CF in a combined state (S400). Referring to FIGS. 4, 6, and 18 together, as described above, the circuit pads FPD of the flexible printed circuit board CF may be coupled to the panel pads PPD of the display panel DP by the conductive adhesive film ACF.

As illustrated in FIG. 18, in determining the degree of alignment of the flexible printed circuit board CF in a combined state (S400), it is possible to measure the degree of alignment of the flexible printed circuit board CF through a vision camera VC. The circuit base layer BL-F includes a lower surface BL-FL on which the circuit pads FPD are disposed and an upper surface BL-FU facing the rear surface BL-FL, and the vision camera VC may measure the degree of alignment in a combined state from the upper surface BL-FU side of the circuit base layer BL-F. The “combined” state refers to a state in which the printed circuit board FPC and the display panel DP are coupled, for example by being pressed together. In the method of manufacturing the display device according to an embodiment of the inventive concept, as the degree of alignment of the flexible printed circuit board CF in a combined state is measured from the direction of the optically transparent circuit base layer BL-F rather than from the direction of the optically opaque panel base layer BL, The alignment state of the circuit alignment pad and the panel alignment pad may be visually assessed.

Each of FIGS. 19A to 19C illustrates a plan view of a step of checking the degree of alignment of the flexible printed circuit board CF in a combined state by measuring the alignment state of the circuit alignment pad F-AM and the panel alignment pad P-AM in the measuring of the degree of alignment in a combined state (S400).

Referring to FIGS. 9B, 19A, 19B, and 19C together, in the measuring of the degree of alignment of the flexible printed circuit board CF in a combined state (S400), it is possible to assess the degree of alignment of the flexible printed circuit board CF in a combined state by measuring the alignment state of the panel alignment pad P-AM. The alignment state of the panel alignment pad P-AM may be checked by comparing the coordinates of the center point CP of the panel alignment pad P-AM with reference point AP or by measuring the distance between the circuit alignment pad F-AM and the panel alignment pad P-AM in at least one of the first direction DR1 or the second direction DR2.

For example, as illustrated in FIGS. 19A and 19B, in the measuring of the degree of alignment of the flexible printed circuit board CF in a combined state (S400), the alignment state may be determined by measuring the coordinates of the center point CP or CP′ of the panel alignment pad P-AM. As illustrated in FIG. 19A, when the coordinates of the center point CP of the panel alignment pad P-AM are measured to completely overlap the reference point AP, it may indicate that the panel alignment pad P-AM is aligned in the first direction DR1 and the second direction DR2 in a state in which the flexible printed circuit board CF is pressed. In contrast, as illustrated in FIG. 19B, when the coordinates of the center point CP′ of the panel alignment pad P-AM is not aligned with the reference point AP in at least one of the first direction DR1 or the second direction DR2, it may indicate that alignment is not achieved. The relative positions of the center point CP′ and the reference point AP provide information about the direction of misalignment—i.e., the first direction DR1 and the second direction. Meanwhile, the reference point AP may be determined based on the positions of the main circuit alignment pad CPP and the first outer circuit alignment pad OPP1 of the circuit alignment pad F-AM. The reference point AP may be the middle point of the first portion P1 and the second portion P2 of the main circuit alignment pad CPP and may be determined as a point spaced apart from the first outer circuit alignment pad OPP1 by a predetermined distance calculated in advance.

Alternatively, as illustrated in FIGS. 19A and 19C, in the measuring of the degree of alignment of the flexible printed circuit board CF in a combined state (S400), it is possible to measure distances a1, a2, a1′, and a2′ between the panel alignment pad P-AM and each of the first portion P1 and the second portion P2 in the first direction DR1. As illustrated in FIG. 19A, if the distances a1 and a2 between the panel alignment pad P-AM and each of the first portion P1 and the second portion P2 in the first direction DR1 meet preset values, it may indicate that alignment is achieved in the first direction DR1 in a state in which the flexible printed circuit board CF is combined with the display panel DP. On the other hand, if the distances a1′ and a2′ between the panel alignment pad P-AM and each of the first portion P1 and the second portion P2 in the first direction DR1 do not meet the preset values as illustrated in FIG. 19C, it may indicate that alignment is not achieved in the first direction DR1 in a state in which the flexible printed circuit board CF is combined with the display panel DP.

In addition, as illustrated in FIGS. 19A and 19C, it is possible to measure the distances b1 and b1′ between the panel alignment pad P-AM and the first outer circuit alignment pad OPP1 in the second direction DR2. As illustrated in FIG. 19A, when the distance b1 between the panel alignment pad P-AM and the first outer circuit alignment pad OPP1 in the second direction DR2 meets a preset value, it may indicate that alignment in the second direction DR2 is achieved in a state in which the flexible printed circuit board CF is combined with the display panel DP, and when the distance b1′ between the panel alignment pad P-AM and the first outer circuit alignment pad OPP1 in the second direction DR2 does not meet a preset value as illustrated in FIG. 19B, it may indicate that alignment in the second direction DR2 is not achieved in a state in which the flexible printed circuit board CF is combined with the display panel DP.

As the method of manufacturing the display device according to an embodiment of the inventive concept includes the measuring of the alignment state after pressing the panel alignment pad P-AM and the circuit alignment pad F-AM which are disposed to avoid overlapping each other, the durability and reliability of the display device manufactured through the method of manufacturing the display device may be improved. In particular, in the display device according to an embodiment of the inventive concept, although the display panel includes an optically opaque panel base layer, it is possible to easily measure the alignment state from the upper surface BL-FU of the circuit base layer BL-F of the flexible printed circuit board after the panel alignment pad P-AM and the circuit alignment pad F-AM are combined. Therefore, the combined state of the flexible printed circuit board may be easily measured when the display device is manufactured, and the reliability of the display device manufactured through the manufacturing method according to an embodiment of the inventive concept may be improved.

According to an embodiment of the inventive concept, after the flexible printed circuit board including a flexible base layer is pressed in the process of combining the flexible printed circuit board and the display panel to each other, it is possible not only to prevent the flexible printed circuit board from being bent, but also to easily measure the degree of alignment of the flexible printed circuit board and the display panel in a pressed state, thus improving the durability and reliability of the process of manufacturing the display device and the display device manufactured therethrough.

Although the above has been described with reference to preferred embodiments of the inventive concept, those skilled in the art or those of ordinary skill in the art will understand that various modifications and changes can be made to the inventive concept within the scope that does not depart from the spirit and technical field of the inventive concept described in the claims to be described later. Accordingly, the technical scope of the inventive concept should not be limited to the content described in the detailed description of the specification, but should be determined by the claims described hereinafter.

What is claimed is:

1. A display device comprising:
a display panel including a plurality of panel pads at least partially extending in a first direction and arranged in a second direction crossing the first direction; and
a flexible circuit board including a plurality of circuit pads at least partially electrically connected to the panel pads,
wherein the plurality of panel pads comprises:
a plurality of display pads extending in the first direction and arranged in the second direction; and
at least one panel alignment pad spaced apart from the plurality of display pads in the second direction,
wherein the plurality of circuit pads comprises:
a plurality of functional pads extending in the first direction, arranged in the second direction, and respectively electrically connected to the plurality of display pads; and
at least one circuit alignment pad extending in the first direction and spaced apart from the functional pads in the second direction,
wherein the at least one circuit alignment pad comprises:
a first portion; and
a second portion spaced apart from the first portion in the first direction to form a separation portion,
wherein the at least one panel alignment pad overlaps the separation portion between the first portion and the second portion or overlaps the separated portion in the second direction.

2. The display device of claim 1, wherein the at least one panel alignment pad overlaps each of the first portion and the second portion in the first direction.

3. The display device of claim 1, wherein the at least one circuit alignment pad comprises:
a first outer circuit alignment pad extending in the first direction; and
a main circuit alignment pad spaced apart from the plurality of functional pads with the first outer circuit alignment pad interposed therebetween,
wherein the main circuit alignment pad includes the first portion and the second portion.

4. The display device of claim 3, wherein a length of the separation portion between the first portion and the second portion in the first direction is greater than a length of the at least one panel alignment pad in the first direction.

5. The display device of claim 3, wherein a width of the main circuit alignment pad in the second direction is greater than a width of the first outer circuit alignment pad in the second direction.

6. The display device of claim 3, wherein a width of each of the first portion and the second portion in the second direction is substantially equal to a width of the panel alignment pad in the second direction.

7. The display device of claim 1, wherein the at least one panel alignment pad comprises:
a first panel alignment pad extending in the first direction; and
a second panel alignment pad extending in the first direction and spaced apart from the first panel alignment pad in the second direction,
wherein the at least one circuit alignment pad is disposed between the first panel alignment pad and the second panel alignment pad.

8. The display device of claim 7, wherein a length of the separation portion between the first portion and the second portion in the first direction is smaller than a length of each of the first panel alignment pad and the second panel alignment pad in the first direction.

9. The display device of claim 7, wherein the ends of the first panel alignment pad and the second panel alignment pad are substantially parallel to each other in the second direction.

10. The display device of claim 1, wherein the display panel further comprises a panel base layer on which the plurality of panel pads are disposed,
wherein the panel base layer is optically opaque.

11. The display device of claim 1, wherein the flexible circuit board further comprises a circuit base layer on which the plurality of circuit pads are disposed,
wherein the circuit base layer is optically transparent.

12. The display device of claim 11, wherein the flexible circuit board has a virtual center line extending halfway between two edges of the circuit base layer that extend in the first direction, and the plurality of circuit pads comprises:
left circuit pads disposed to the left side of the virtual center line; and
right circuit pads disposed to the right side of the virtual center line,
wherein the left circuit pads comprise:
a plurality of first functional pads extending in the first direction, arranged in the second direction, and respectively electrically connected to the plurality of display pads; and
at least one first circuit alignment pad extending in the first direction and spaced apart from the first functional pads in the second direction,
wherein the right circuit pads comprise:
a plurality of second functional pads extending in the first direction, arranged in the second direction, and respectively electrically connected to the plurality of display pads; and
at least one second circuit alignment pad extending in the first direction and spaced apart from the second functional pads in the second direction,
wherein the at least one first circuit alignment pad comprises:
a (1-1)-th portion; and
a (2-1)-th portion spaced apart from the (1-1)-th portion in the first direction,
wherein the at least one second circuit alignment pad comprises:
a (1-2)-th portion; and
a (2-2)-th portion spaced apart from the (1-2)-th portion in the first direction.

13. The display device of claim 1, further comprising a data driving circuit connected to at least some of the plurality of functional pads.

14. The display device of claim 1, further comprising a conductive adhesive film disposed between the display panel and the flexible circuit board and electrically connecting the plurality of display pads to the plurality of functional pads.

15. A display device comprising:
a display panel including an optically opaque panel base layer and a plurality of panel pads disposed on the panel base layer, at least partially extending in a first direction, and arranged in a second direction crossing the first direction; and
a flexible circuit board coupled to the display panel and including a plurality of circuit pads at least partially electrically connected to the plurality of panel pads,
wherein the plurality of panel pads comprises:
a plurality of display pads extending in the first direction and arranged in the second direction; and
at least one panel alignment pad spaced apart from the plurality of display pads in the second direction,
wherein the plurality of circuit pads comprises:
a plurality of functional pads extending in the first direction, arranged in the second direction, and respectively electrically connected to the plurality of display pads; and
at least one circuit alignment pad spaced apart from the plurality of functional pads in the second direction,
wherein the at least one circuit alignment pad comprises:
a first portion; and
a second portion spaced apart from the first portion in the first direction,
wherein the at least one panel alignment pad is disposed to avoid overlapping the plurality of circuit pads.

16. The display device of claim 15, wherein the at least one panel alignment pad overlaps the at least one circuit alignment pad in any one of the first direction and the second direction.

17. The display device of claim 15, wherein the flexible circuit board further comprises a circuit base layer on which the plurality of circuit pads are disposed, wherein the circuit base layer includes a flexible material that is optically transparent.

18. A method for manufacturing a display device, the method comprising:
providing a display panel including a display region that displays an image and a non-display region adjacent to the display region and including a plurality of display pads disposed in the non-display region and at least one panel alignment pad;
providing a flexible circuit board including a plurality of functional pads and at least one circuit alignment pad;
combining the display panel and the flexible circuit board to electrically connect at least some of the plurality of functional pads to the plurality of display pads; and
determining the degree of alignment of the flexible circuit board with the display panel,
wherein:
the plurality of display pads, the plurality of functional pads, and the at least one circuit alignment pad extend in a first direction; and
the plurality of functional pads and the at least one circuit alignment pad are spaced apart from each other in a second direction crossing the first direction,
wherein the at least one circuit alignment pad comprises:
a first portion; and
a second portion spaced apart from the first portion in the first direction,
wherein, in the measuring of the degree of alignment in the combined state, the state of alignment between the at least one panel alignment pad and the at least one circuit alignment pad is measured.

19. The method of claim 18, wherein the flexible circuit board further comprises a circuit base layer including a rear surface on which the plurality of circuit pads are disposed and a front surface opposing the rear surface,
wherein, in the determining of the degree of alignment, the state of alignment between the at least one panel alignment pad and the at least one circuit alignment pad is measured from the front surface side.

20. The method of claim 18, wherein the display panel further comprises a panel base layer on which the plurality of panel pads are disposed,
wherein the panel base layer is optically opaque.
